(19) United States
(12) Patent Application Publication
(10) Pub. No.: US 2023/0359123 A1
(43) Pub. Date: Nov. 9, 2023

(54) RESIST UNDERLAYER FILM-FORMING COMPOSITION

(71) Applicant: NISSAN CHEMICAL CORPORATION, Tokyo (JP)

(72) Inventors: Hikaru TOKUNAGA, Toyama-shi (JP); Makoto NAKAJIMA, Toyama-shi (JP); Hirokazu NISHIMAKI, Toyama-shi (JP)

(73) Assignee: NISSAN CHEMICAL CORPORATION, Tokyo (JP)

(21) Appl. No.: 18/017,532

(22) PCT Filed: Aug. 3, 2021
(86) PCT No.: PCT/JP2021/028714

§ 371 Date: Jan. 23, 2023

(30) Foreign Application Priority Data
Aug. 5, 2020 (JP) 2020-132896

(51) Int. Cl. G03F 7/11; H01L 21/027; H01L 21/033; H01L 21/48

(52) U.S. Cl. CPC G03F 7/11; H01L 21/0275; H01L 21/0337; H01L 21/4803

(57) ABSTRACT

A composition for forming a resist underlayer film includes: a solvent; and a polymer containing a unit structure (A) represented by formula (1). The composition is reduced in the amount of sublimated substances that contaminate a device, is improved in the in-plane uniform coatability of a film to be coated thereon, exhibits satisfactory resistance to a chemical solution used in a resist under layer film, and can exhibit other satisfactory properties.

### TECHNICAL FIELD

The present invention relates to a resist underlayer film-forming composition, a resist underlayer film, which is a baked product of a coating film containing the composition, and a method for producing a semiconductor device using the composition.

### BACKGROUND ART

In recent years, there has been a need for a resist underlayer film-forming composition for use in the lithography process of semiconductor device manufacturing that does not intermix with the upper layer, produces an excellent resist pattern, and has a smaller dry etching rate than the upper layer (hard mask: coating film or vapor-deposited film) or semiconductor substrate. And the use of a polymer having a repeating unit containing a benzene ring or a naphthalene ring has been proposed (Patent Literature 1).

### CITATION LIST

### Patent Literature

Patent Literature 1: WO 2013/047516 A1

### SUMMARY OF INVENTION

### Technical Problem

However, the conventional resist underlayer film-forming compositions are still unsatisfactory in terms of requirements such as reducing the amount of sublimates that would contaminate the apparatus and improving the in-plane uniform application property of the coating film. In the semiconductor manufacturing process, treatment with chemical solutions may be carried out, and in such cases, the resist underlayer film may be required to have a sufficient resistance to the chemical solutions used.

### Solution to Problem

The present invention solves the above problems. That is, the present invention includes the followings.
[1] A resist underlayer film-forming composition comprising a solvent and a polymer comprising a unit structure (A) represented by the following formula (1):

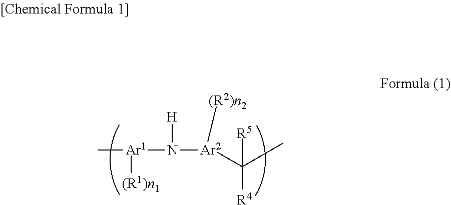

wherein Ar¹ and Ar² each represent a benzene ring or naphthalene ring, Ar¹ and Ar² may be bonded via a single bond;
R¹ and R² are groups substituting hydrogen atoms on the rings of Ar¹ and Ar², respectively, and are selected from the group consisting of a halogen atom, a nitro group, an amino group, a cyano group, an alkyl group having 1 to 10 carbon atoms, an alkenyl group having 2 to 10 carbon atoms, an alkynyl group having 2 to 10 carbon atoms, an aryl group having 6 to 40 carbon atoms, and combinations thereof, and the alkyl, alkenyl, alkynyl, and aryl groups may contain an ether, ketone, or ester bond,
R⁴ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, and an aryl group having 6 to 40 carbon atoms, and the alkyl, alkenyl, alkynyl, and aryl groups may contain ether, ketone, or ester bonds;
R⁵ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms, and the alkyl, alkenyl, alkynyl, and aryl groups may contain ether, ketone, or ester bonds;
R⁴ and R⁵ may be combined with a carbon atom to which they are bonded to form a ring; and
n1 and n2 are each an integer of from 0 to 3.
[2] The resist underlayer film-forming composition according to [1], wherein Ar¹ and Ar² in formula (1) are benzene rings.
[3] The resist underlayer film-forming composition according to [1] or [2], wherein R⁵ in formula (1) is a hydrogen atom, R⁴ is an aryl group having 6 to 40 carbon atoms, the aryl group may be substituted with a halogen group, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms.
[4] The resist underlayer film-forming composition according to any one of [1] to [3], wherein R⁵ in formula (1) is a hydrogen atom, R⁴ is an aryl group having 6 to 40 carbon atoms, and the aryl group may be substituted with an aryl group having 6 to 40 carbon atoms.
[5] The resist underlayer film-forming composition according to any one of [1] to [4], wherein R⁵ in formula (1) is a hydrogen atom, and R⁴ is a group comprising a combination of optionally substituted benzene rings.
[6] The resist underlayer film-forming composition according to any one of [1] to [5], further including a cros slinking agent.
[7] The resist underlayer film-forming composition according to any one of [1] to [6], further comprising an acid and/or an acid generator.
[8] The resist underlayer film-forming composition according to [1], wherein the solvent has a boiling point of 160° C. or higher.
[9] A resist underlayer film, which is a baked product of a coating film comprising the resist underlayer film-forming composition according to any one of [1] to [8].
[10] A method for producing a semiconductor device, comprising the steps of:
forming a resist underlayer film on a semiconductor substrate using the resist underlayer film-forming composition according to any one of [1] to [8];
forming a resist film on the formed resist underlayer film;
forming a resist pattern by irradiating the formed resist film with a light or electron beam followed by development;
etching and patterning the resist underlayer film through the formed resist pattern; and
processing the semiconductor substrate through the patterned resist underlayer film.
[11] A method for producing a semiconductor device, comprising the steps of:
forming a resist underlayer film on a semiconductor substrate using the resist underlayer film-forming composition according to any one of [1] to [8];
forming a hard mask on the formed resist underlayer film;
forming a resist film on the formed hard mask;
forming a resist pattern by irradiating the formed resist film with a light or electron beam followed by development;
etching the hard mask through the formed resist pattern;
etching the resist underlayer film through the etched hard mask; and
removing the hard mask.
The method for producing a semiconductor device according to [11], further comprising the steps of:
forming a vapor-deposited film (spacer) on the underlayer film from which the hard mask has been removed;
processing the formed vapor-deposited film (spacer) by etching;
removing the underlayer film; and
processing the semiconductor substrate with the spacer.
[13] The method for producing a semiconductor device according to any one of [10] to [12], wherein the semiconductor substrate is a stepped substrate.
[14] A polymer comprising a unit structure (A) represented by the following formula (1):

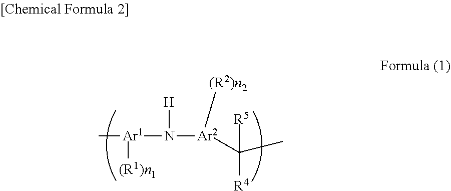

wherein Ar¹ and Ar² each represent a benzene ring or naphthalene ring, Ar¹ and Ar² may be bonded via a single bond;
R¹ and R² are groups substituting hydrogen atoms on the rings of Ar¹ and Ar², respectively, and are selected from the group consisting of a halogen atom, a nitro group, an amino group, a cyano group, an alkyl group having 1 to 10 carbon atoms, an alkenyl group having 2 to 10 carbon atoms, an alkynyl groups having 2 to 10 carbon atoms, an aryl groups having 6 to 40 carbon atoms, and combinations thereof, and the alkyl, alkenyl, alkynyl, and aryl groups may contain an ether, ketone, or ester bond,
R⁴ is a group including a combination of optionally substituted benzene rings including a biphenyl group, the benzene ring may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms, and the alkyl, alkenyl, alkynyl, and aryl groups may contain an ether, ketone, or ester bond,
R⁵ is a hydrogen atom, and
n1 and n2 are each an integer of from 0 to 3.
[15] The polymer according to [14], wherein Ar¹ and Ar² in formula (1) are benzene rings.
[16] The polymer according to [14], wherein R⁴ in formula (1) is an optionally substituted biphenyl group.

### Advantageous Effects of Invention

The present invention provides a novel resist underlayer film-forming composition that can reduce the amount of sublimates that would contaminate the apparatuses, improve the uniformity of in-plane application property of the coating film, and exhibit other favorable properties such as sufficient resistance to chemical solutions that may be used for resist underlayer film.

### Description of Embodiments

### Resist Underlayer Film-Forming Composition

The resist underlayer film-forming composition of the present invention contains a solvent and a polymer containing a unit structure (A) represented by the following formula (1):

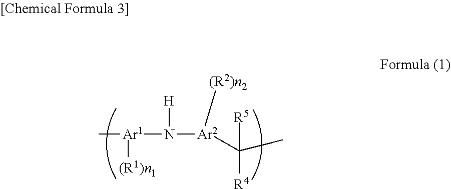

wherein Ar¹ and Ar² each represent a benzene ring or naphthalene ring, Ar¹ and Ar² may be bonded via a single bond;
R¹ and R² are groups substituting hydrogen atoms on the rings of Ar¹ and Ar², respectively, and are selected from the group consisting of a halogen atom, a nitro group, an amino group, a cyano group, an alkyl group having 1 to 10 carbon atoms, an alkenyl group having 2 to 10 carbon atoms, an alkynyl group having 2 to 10 carbon atoms, an aryl group having 6 to 40 carbon atoms, and combinations thereof, and the alkyl, alkenyl, alkynyl, and aryl groups may contain an ether, ketone, or ester bond,
R⁴ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, and an aryl group having 6 to 40 carbon atoms, and the alkyl, alkenyl, alkynyl, and aryl groups may contain an ether, ketone, or ester bond;
R⁵ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms, and the alkyl, alkenyl, alkynyl, and aryl groups may contain an ether, ketone, or ester bond;
R⁴ and R⁵ may be combined with a carbon atom to which they are bonded to form a ring; and
n1 and n2 are each an integer of from 0 to 3.

### Polymer Containing Unit Structure (A) Represented by Formula (1)

Ar¹ and Ar² each represent a benzene or naphthalene ring.

Ar¹ and Ar² may be bonded via a single bond to form a carbazole skeleton, for example.

It is preferred that Ar¹ and Ar² are both benzene rings.

R¹ and R² are groups substituting hydrogen atoms on the rings of Ar¹ and Ar², and are selected from the group consisting of a halogen atom, a nitro group, an amino group, a cyano group, an alkyl group having 1 to 10 carbon atoms, an alkenyl group having 2 to 10 carbon atoms, an alkynyl groups having 2 to 10 carbon atoms, an aryl group having 6 to 40 carbon atoms, and combinations thereof, wherein the alkyl, alkenyl, alkynyl, and aryl groups may contain an ether, ketone, or ester bond.

Examples of the halogen atom include fluorine, chlorine, bromine, and iodine.

Examples of the alkyl group having 1 to 10 carbon atoms include methyl, ethyl, n-propyl, i-propyl, n-butyl, i-butyl, s-butyl, t-butyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2 trimethyl-n-propyl, 1,2,2-trimethyl-n-propyl, 1-ethyl-1-methyl-n-propyl, and 1-ethyl-2-methyl-n-propyl groups.

The group may be a cyclic alkyl group, such as cyclopropyl, cyclobutyl, 1-methyl-cyclopropyl, 2-methyl-cyclopropyl, cyclopentyl, 1-methyl-cyclobutyl, 2-methyl-cyclobutyl, 3-methyl-cyclobutyl, 1,2-dimethyl-cyclopropyl, 2,3-dimethyl-cyclopropyl, 1-ethyl-cyclopropyl, 2-ethyl-cyclopropyl, cyclohexyl, 1-methyl-cyclopentyl, 2-methyl-cyclopentyl, 3-methyl-cyclopentyl, 1-ethyl cyclobutyl, 2-ethyl-cyclobutyl, 3-ethyl-cyclobutyl, 1,2-dimethyl-cyclobutyl, 1,3-dimethyl-cyclobutyl, 2,2-dimethyl-cyclobutyl, 2,3-dimethyl-cyclobutyl, 2,4-dimethyl-cyclobutyl, 3,3-dimethyl-cyclobutyl, 1-n-propyl-cyclopropyl, 2-n-propyl-cyclopropyl, 1-i-propyl-cyclopropyl, 2-i-propyl-cyclopropyl, 1,2,2-trimethyl-cyclopropyl, 1,2,3-trimethyl-cyclopropyl, 2,2,3-trimethyl-cyclopropyl, 1-ethyl-2-methyl-cyclopropyl, 2-ethyl-1-methyl-cyclopropyl, 2-ethyl-2-methyl-cyclopropyl, and 2-ethyl-3-methyl-cyclopropyl groups.

Examples of the alkenyl group having 2 to 10 carbon atoms include ethenyl, 1-propenyl, 2-propenyl, 1-methyl-1-ethenyl, 1-butenyl, 2-butenyl, 3-butenyl, 2-methyl-1-propenyl, 2-methyl-2-propenyl, 1-ethylethenyl, 1-methyl-1-propenyl, 1-methyl-2-propenyl, 1-pentenyl, 2-pentenyl, 3-pentenyl, 4-pentenyl, 1-n-propyl ethenyl, 1-methyl-1-butenyl, 1-methyl-2-butenyl, 1-methyl-3-butenyl, 2-ethyl-2 propenyl, 2-methyl-1-butenyl, 2-methyl-2-butenyl, 2-methyl-3-butenyl, 3-methyl-1-butenyl, 3-methyl-2-butenyl, 3-methyl-3-butenyl, 1,1-dimethyl-2-propenyl, 1-i-propyl ethenyl, 1,2-dimethyl-1-propenyl, 1,2-dimethyl-2-propenyl, 1-cyclopentenyl, 2-cyclopentenyl, 3-cyclopentenyl, 1-hexenyl, 2-hexenyl, 3-hexenyl, 4-hexenyl, 5-hexenyl, 1-methyl-1-pentenyl, 1-methyl-2-pentenyl, 1-methyl-3-pentenyl, 1-methyl-4-pentenyl, 1-n-butylethenyl, 2-methyl-1-pentenyl, 2-methyl-2-pentenyl, 2-methyl-3-pentenyl, 2-methyl-4-pentenyl, 2-n-propyl-2-propenyl, 3-methyl-1-pentenyl, 3-methyl-2-pentenyl, 3-methyl-3-pentenyl, 3-methyl-4-pentenyl, 3-ethyl-3-butenyl, 4-methyl-1-pentenyl, 4-methyl-2-pentenyl, 4-methyl-3-pentenyl, 4-methyl-4-pentenyl, 1,1-dimethyl-2-butenyl, 1,1-dimethyl-3-butenyl, 1,2-dimethyl-1-butenyl, 1,2-dimethyl-2-butenyl, 1,2-dimethyl-3-butenyl, 1-methyl-2-ethyl-2-propenyl, 1-s-butylethenyl, 1,3-dimethyl-1-butenyl, 1,3-dimethyl-2-butenyl, 1,3-dimethyl-3-butenyl, 1-i-butylethenyl, 2,2-dimethyl-3-butenyl, 2,3-dimethyl-1-butenyl, 2,3-dimethyl-2-butenyl, 2,3-dimethyl-3-butenyl, 2-i-propyl-2-propenyl, 3,3-dimethyl-1-butenyl, 1-ethyl-1-butenyl, 1-ethyl-2-butenyl, 1-ethyl-3-butenyl, 1-n-propyl-1-propenyl, 1-n-propyl-2-propenyl, 2-ethyl-1-butenyl, 2-ethyl-2-butenyl, 2-ethyl-3-butenyl, 1,1,2-trimethyl-2-propenyl, 1-t-butylethenyl, 1-methyl-1-ethyl-2-propenyl, 1-ethyl-2-methyl-1-propenyl, 1-ethyl-2-methyl-2-propenyl, 1-i-propyl-1-propenyl, 1-i-propyl-2-propenyl, 1-methyl-2-cyclopentenyl, 1-methyl-3-cyclopentenyl, 2-methyl-1-cyclopentenyl, 2-methyl-2-cyclopentenyl, 2-methyl-3-cyclopentenyl, 2-methyl-4-cyclopentenyl, 2-methyl-5-cyclopentenyl, 2-methylene-cyclopentyl, 3-methyl-1-cyclopentenyl, 3-methyl-2-cyclopentenyl, 3-methyl-3-cyclopentenyl, 3-methyl-4-cyclopentenyl, 3-methyl-5-cyclopentenyl, 3-methylene-cyclopentyl, 1-cyclohexenyl, 2-cyclohexenyl, and 3-cyclohexenyl groups.

Examples of the alkynyl groups having 2 to 10 carbon atoms include ethynyl, 1-propynyl, and 2-propynyl groups.

Examples of the aryl groups having 6 to 40 carbon atoms include phenyl, benzyl, naphthyl, anthracenyl, phenanthrenyl, naphthacenyl, triphenylenyl, pyrenyl, and chrysenyl groups.

The above alkyl, alkenyl, alkynyl, and aryl groups may contain an ether (—O—), ketone (—CO—), or ester (—COO—, —OCO—) bond.

R⁴ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, and an aryl group having 6 to 40 carbon atoms, and the alkyl, alkenyl, alkynyl, and aryl groups may contain an ether, ketone, or ester bond.

R⁵ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano groups, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, and an aryl group having 6 to 40 carbon atoms, and the alkyl, alkenyl, alkynyl, and aryl groups may contain an ether, ketone, or ester bond.

The heterocyclic group is a substituent derived from a heterocyclic compound, and specific examples thereof include thiophene, furan, pyridine, pyrimidine, pyrazine, pyrrole, oxazole, thiazole, imidazole, quinoline, carbazole, quinazoline, purine, indolizine, benzothiophene, benzofuran, indole, acridine, isoindole, benzoimidazole, isoquinoline, quinoxaline, cinnoline, pteridine, chromene (benzopyran), isochromene (benzopyran), xanthene, thiazole, pyrazole, imidazoline, and azine groups. Of these, thiophene, furan, pyridine, pyrimidine, pyrazine, pyrrole, oxazole, thiazole, imidazole, quinoline, carbazole, quinazoline, purine, indolizine, benzothiophene, benzofuran, indole, and acridine groups are preferred, and thiophene, furan, pyridine, pyrimidine, pyrrole, oxazole, thiazole, imidazole, and carbazole groups are most preferred.

Examples of the alkoxy group having 1 to 10 carbon atoms include groups in which an etheric oxygen atom (—O—) is bonded to the terminal carbon atom of the above-mentioned alkyl group having 1 to 10 carbon atoms. Examples of the alkoxy group include methoxy, ethoxy, n-propoxy, i-propoxy, cyclopropoxy, n-butoxy, i-butoxy, s-butoxy, t-butoxy, cyclobutoxy, 1-methyl-cyclopropoxy, 2-methyl-cyclopropoxy, n-pentoxy, 1-methyl-n-butoxy, 2-methyl-n-butoxy, 3-methyl-n-butoxy, 1,1-dimethyl-n-propoxy, 1,2-dimethyl-n-propoxy, 2,2-dimethyl-n-propoxy, 1-ethyl-n-propoxy, 1,1-diethyl-n-propoxy, cyclopentoxy, 1-methyl-cyclobutoxy, 2-methyl-cyclobutoxy, 3-methyl-cyclobutoxy, 1,2-dimethyl-cyclopropoxy, 2,3-dimethyl-cyclopropoxy, 1-ethyl-cyclopropoxy, and 2-ethyl-cyclopropoxy groups.

R⁴ and R⁵ may be combined with a carbon atom to which they are bonded to form a ring (for example, a fluorene ring).

n1 and n2 are each an integer of from 0 to 3.

Of the polymers containing unit structure (A) represented by formula (1), preferable examples are as follows.
A polymer containing unit structure (A) represented by formula (1), or a polymer represented by formula (1), wherein R⁵ is a hydrogen atom and R⁴ is an aryl group having 6 to 40 carbon atoms, the aryl group may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms.
A polymer containing unit structure (A) represented by formula (1), or a polymer represented by formula (1), wherein R⁵ is a hydrogen atom and R⁴ is an aryl group having 6 to 40 carbon atoms, the aryl group may be substituted with an aryl group having 6 to 40 carbon atoms.
A polymer containing unit structure (A) represented by formula (1), or a polymer represented by formula (1), wherein R⁵ is a hydrogen atom and R⁴ is a group containing a combination of optionally substituted benzene rings.
A polymer containing unit structure (A) represented by formula (1), or a polymer represented by formula (1), wherein R⁵ is a hydrogen atom and R⁴ is a group containing a combination of optionally substituted benzene rings including a biphenyl group.
A polymer containing unit structure (A) represented by formula (1), or a polymer represented by formula (1), wherein R⁵ is a hydrogen atom and R⁴ is a group containing a combination of optionally substituted benzene rings including a biphenyl group, and Ar¹ and Ar² are benzene rings.
A polymer containing unit structure (A) represented by formula (1), or a polymer represented by formula (1), wherein R⁵ is a hydrogen atom and R⁴ is an optionally substituted biphenyl group.
A polymer containing unit structure (A) represented by formula (1), or a polymer represented by formula (1), wherein R⁵ is a hydrogen atom, R⁴ is a biphenyl group, and Ar¹ and Ar² are benzene or naphthalene rings.

### Solvent

The solvent for the resist underlayer film-forming composition of the present invention is not particularly limited as long as it is a solvent that can dissolve the compound represented by formula (1). In particular, since the resist underlayer film-forming composition of the present invention is used in a homogeneous solution state, it is recommended that it be used in combination with a solvent commonly used in the lithography process, considering its application property.

Examples of the solvent include methyl cellosolve acetate, ethyl cellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoether ether acetate, propylene glycol monopropyl ether acetate, propylene glycol monobutyl ether acetate, toluene, xylene, methyl ethyl ketone, cyclopentanone, cyclohexanone, ethyl 2-hydroxy propionate, ethyl 2-hydroxy-2-methyl propionate, ethyl ethoxyacetate, ethyl hydroxyacetate, 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl pyrrolidone, 4-methyl-2-pentanol, and γ-butyrolactone. These solvents may be used each alone or in combination of two or more thereof.

The following compounds listed in WO2018/131562A1 may also be used:

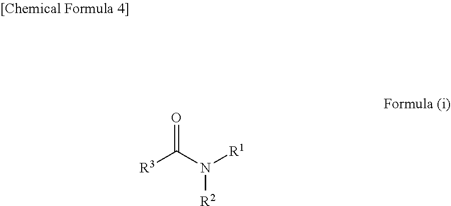

wherein R^{1,} R² and R³ in formula (i) each represent a hydrogen atom, an oxygen atom, a sulfur atom, or an alkyl group having 1 to 20 carbon atoms, which may be interrupted by an amide bond, may be identical or different from each other, and may be bonded to each other to form a ring structure.

Examples of the alkyl group having 1 to 20 carbon atoms include linear or branched alkyl groups with or without substituents, such as methyl, ethyl, n-propyl, isopropyl, n-butyl, sec-butyl, tert-butyl, n-pentyl, isopentyl, neopentyl, n-hexyl, isohexyl, n-heptyl, n-octyl, cyclohexyl, 2-ethylhexyl, n-nonyl, isononyl, p-tert-butylcyclohexyl, n-decyl, n-dodecylnonyl, undecyl, dodecyl, tridecyl, tetradecyl, pentadecyl, hexadecyl, heptadecyl, octadecyl nonadecyl, nonadecyl, and eicosyl groups. Of these alkyl groups having 1 to 12 carbon atoms are preferred, alkyl groups having 1 to 8 carbon atoms are more preferred, and alkyl groups having 1 to 4 carbon atoms are even more preferred.

Examples of the alkyl group having 1 to 20 carbon atoms interrupted by an oxygen atom, sulfur atom, or amide bond include those containing the structural unit —CH₂—O—, —CH₂—S—, —CH₂—NHCO—, or —CH₂—CONH—. The alkyl group may contain one or more units of —O—, —S—, —NHCO— or —CONH— therein. Specific examples of the alkyl group having 1 to 20 carbon atoms interrupted by —O—, —S—, —NHCO— or —CONH— unit include methoxy, ethoxy, propoxy, butoxy, methylthio, ethylthio, propylthio, butylthio, methylcarbonylamino, ethylcarbonylamino, propylcarbonylamino, butylcarbonylamino, methylaminocarbonyl, ethylaminocarbonyl, propylaminocarbonyl, and butylaminocarbonyl. Other examples include methyl, ethyl, propyl, butyl, pentyl, hexyl, heptyl, octyl, nonyl, decyl, dodecyl, or octadecyl groups substituted with a methoxy, ethoxy, propoxy, butoxy, methylthio, ethylthio, propylthio, butylthio, methylcarbonylamino, ethylcarbonylamino, methylaminocarbonyl, or ethylaminocarbonyl group. Of these, methoxy, ethoxy, methylthio, and ethylthio groups are preferred, and methoxy and ethoxy groups are more preferred.

Since these solvents have a relatively high boiling point, they are also effective in imparting high embedding and high planarization properties to the resist underlayer film-forming composition.

The following are specific examples of preferred compounds represented by formula (i).

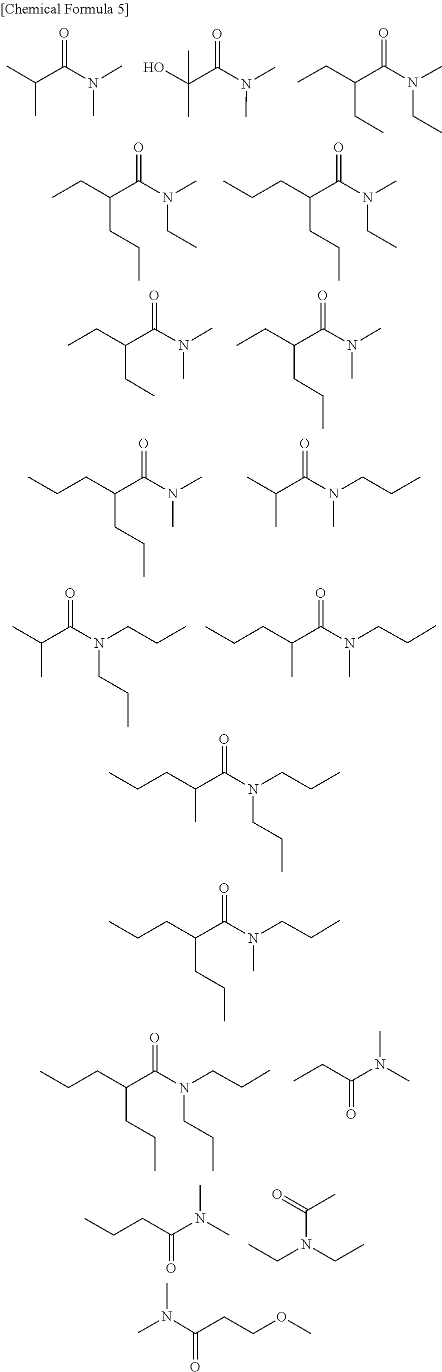

Of the above compounds, 3-methoxy-N,N-dimethylpropionamide, N,N-dimethylisobutyramide, and compounds represented by the following formula are preferable, and the compound represented by formula (i) is particularly preferably 3-methoxy-N,N-dimethylpropionamide or N,N-dimethylisobutylamide:

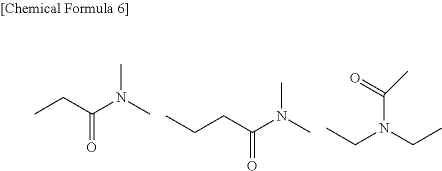

These solvents may be used each alone or in combination of two or more thereof. Of these solvents, those having a boiling point of 160° C. or higher are preferred, such as propylene glycol monomethyl ether, propylene glycol monomethyl ether acetate, ethyl lactate, butyl lactate, cyclohexanone, 3-methoxy-N,N-dimethylpropionamide, N,N-dimethylisobutylamide, 2,5-dimethylhexane-1,6-diyl diacetate (DAH; CAS 89182-68-3), and 1,6-diacetoxyhexane (CAS 6222-17-9). Propylene glycol monomethyl ether, propylene glycol monomethyl ether acetate, and N,N-dimethylisobutylamide are particularly preferred.

These solvents may be used each alone or in combination of two or more thereof. The solid content ratio of the composition, excluding organic solvents, is, for example, within the range of from 0.5% to 30% by mass, and preferably from 0.8% to 15% by mass.

### Optional Components

The resist underlayer film-forming composition of the present invention may further contain at least one of crosslinking agent, acid and/or acid generator, thermal acid generator, and surfactant as optional components.

### Crosslinking Agent

The resist underlayer film-forming composition of the present invention may further contain a crosslinking agent. The crosslinking agent is preferably a crosslinking compound having at least two crosslink-forming substituents. Examples thereof include melamine, substituted urea, and phenol compounds having crosslink-forming substituents such as methylol and methoxymethyl groups, or their polymers. Specific examples of the compound include methoxymethylated glycoluryl, butoxymethylated glycoluryl, methoxymethylated melamine, butoxymethylated melamine, methoxymethylated benzoguanamine, and butoxymethylated benzoguanamine, such as tetramethoxymethylglycoluril (for example, PL-LI (tetrakis(methoxymethyl)glycoluril manufactured by Midori Kagaku Co., Ltd.), tetrabutoxymethylglycoluril, and hexamethoxymethylmelamine). Examples of the substituted urea compound include methoxymethylated urea, butoxymethylated urea, and methoxymethylated thiourea, such as tetramethoxymethylurea and tetrabutoxymethylurea. Condensates of these compounds may also be used. Examples of the phenolic compound include tetrahydroxymethylbiphenol, tetramethoxymethylbiphenol, tetrahydroxymethylbisphenol, tetramethoxymethylbisphenol, and compounds represented by the following formula:

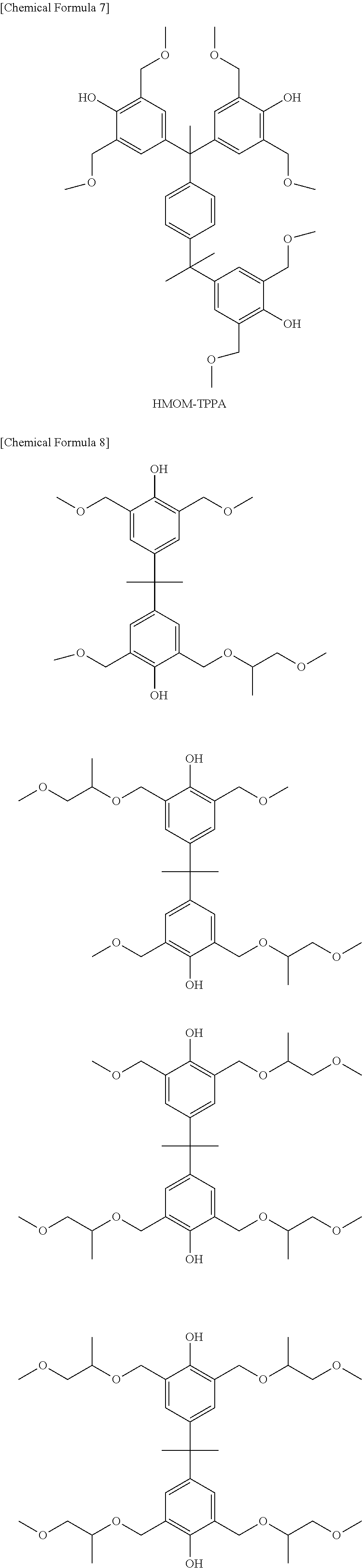

The crosslinking agent may be a compound having at least two epoxy groups. Examples of the compound include tris(2,3-epoxypropyl)isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidylphenyl glycidyl ether, 1,1,3-tris[p-(2,3-epoxypropoxy)phenyl]propane, 1,2-cyclohexanedicarboxylic acid diglycidyl ester, 4,4′-methylenebis(N,N-diglycidylaniline), 3,4-epoxycyclohexylmethyl-3,4-epoxycyclohexanecarboxylate, trimethylol ethane triglycidyl ether, bisphenol-A-diglycidyl ether, Epolead [registered trademark] GT-401, GT-403, GT-301, GT-302, Celloxide [registered trademark] 2021, and 3000 manufactured by Daicel Corporation, 1001, 1002, 1003, 1004, 1007, 1009, 1010, 828, 807, 152, 154, 180S75, 871, and 872 manufactured by Mitsubishi Chemical Corporation, EPPN201, 202, EOCN-102, 103S, 104S, 1020, 1025, and 1027 manufactured by Nippon Kayaku Co., Ltd., Denacol [registered trademark] EX-252, EX-611, EX-612, EX-614, EX-622, EX-411, EX-512, EX-522, EX-421, EX-313, EX-314, and EX-321 manufactured by Nagase ChemteX Corporation, CY175, CY177, CY179, CY182, CY184, and CY192 manufactured by BASF Japan Ltd., and Epiclon 200, 400, 7015, 835LV, and 850CRP manufactured by DIC Corporation. The compound having at least two epoxy groups may also be an epoxy resin having an amino group. Examples of the epoxy resin include YH-434 and YH-434L (manufactured by NSCC Epoxy Manufacturing Co., Ltd.).

The crosslinking agent may be a compound having at least two blocked isocyanate groups. Examples of the compound include Takenate [registered trademark] B-830 and B-870N manufactured by Mitsui Chemicals, Inc. and VESTANAT [registered trademark] B1358/100 manufactured by Evonik Degussa GmbH.

The crosslinking agent may be a compound having at least two vinyl ether groups. Examples of the compound include bis(4-(vinyloxymethyl)cyclohexylmethyl)glutarate, tri(ethylene glycol) divinyl ether, adipic acid divinyl ester, diethylene glycol divinyl ether, 1,2,4-tris(4-vinyloxibutyl) trimellitate, 1,3,5-tris(4-vinyloxybutyl)trimellitate, bis(4-(vinyloxy)butyl)terephthalate, bis(4-(vinyloxy)butyl)isophthalate, ethylene glycol divinyl ether, 1,4-butanediol divinyl ether, tetramethylene glycol divinyl ether, tetraethylene glycol divinyl ether, neopentyl glycol divinyl ether, trimethylolpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether.

The crosslinking agent may also be a highly heat-resistant cros slinking agent. The highly heat-resistant crosslinking agent is preferably a compound containing a crosslink-forming substituent with an aromatic ring (for example, benzene or naphthalene ring) in the molecule.

Examples of the compound include compounds having the partial substructure of the following formula (4) and polymers or oligomers having the repeating units of the following formula (5).

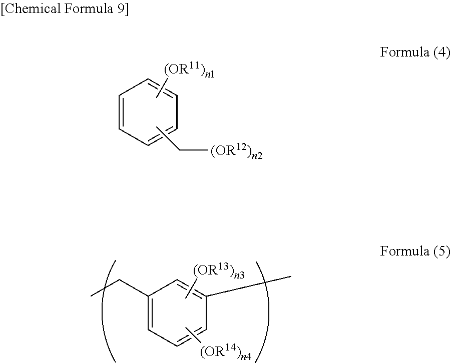

The above R¹¹, R¹², R¹³, and R¹⁴ are hydrogen atoms or an alkyl group having 1 to 10 carbon atoms, and the above examples may apply to the alkyl group. n1 is an integer of from 1 to 4, n2 is an integer of from 1 to (5−n1), and (n1+n2) represents an integer of from 2 to 5. n3 is an integer of from 1 to 4, n4 is from 0 to (4−n3), and (n3+n4) represents an integer of from 1 to 4. The number of repeating unit structures of the oligomers and polymers may range from 2 to 100 or 2 to 50.

Examples of the compounds, polymers and oligomers of formulas (4) and (5) are listed below.

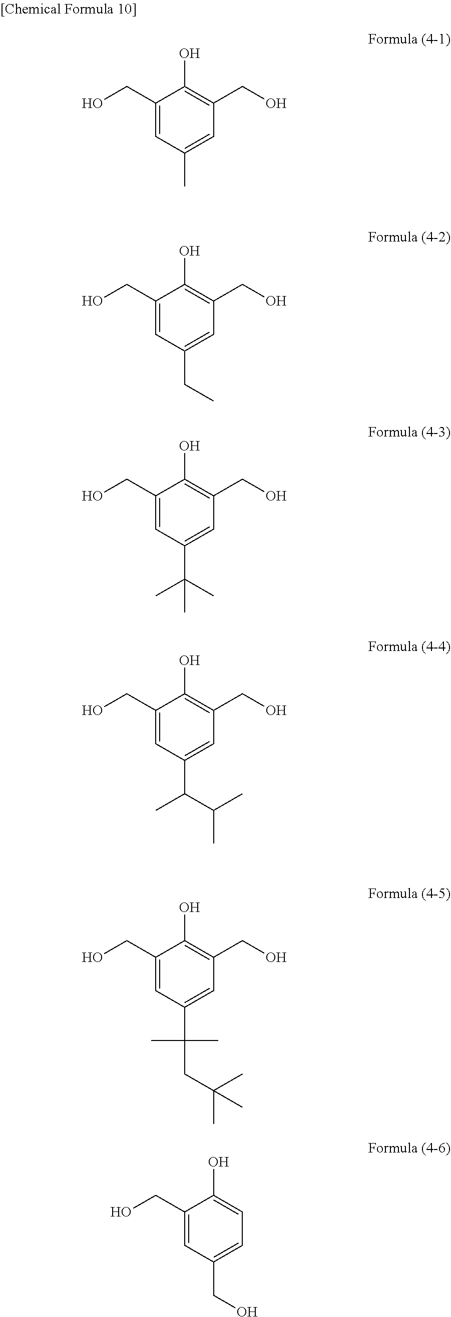

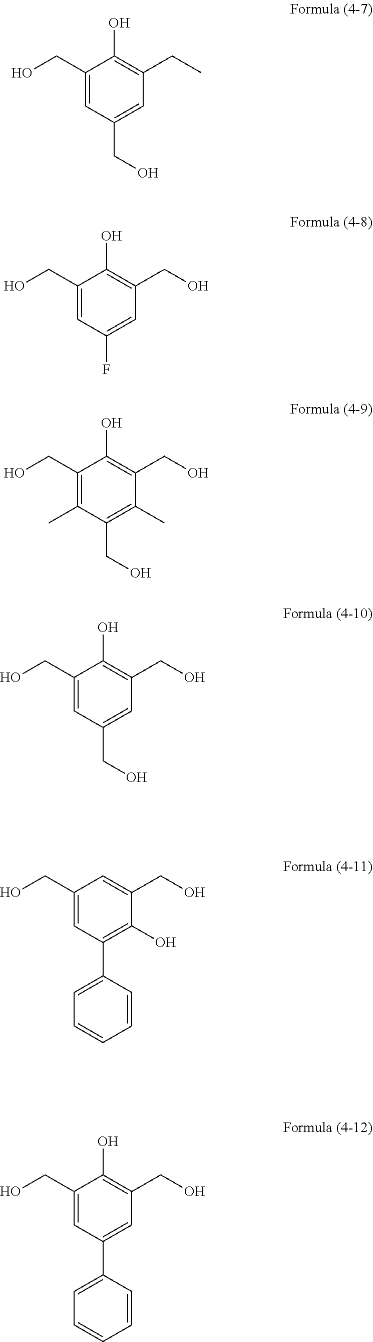 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

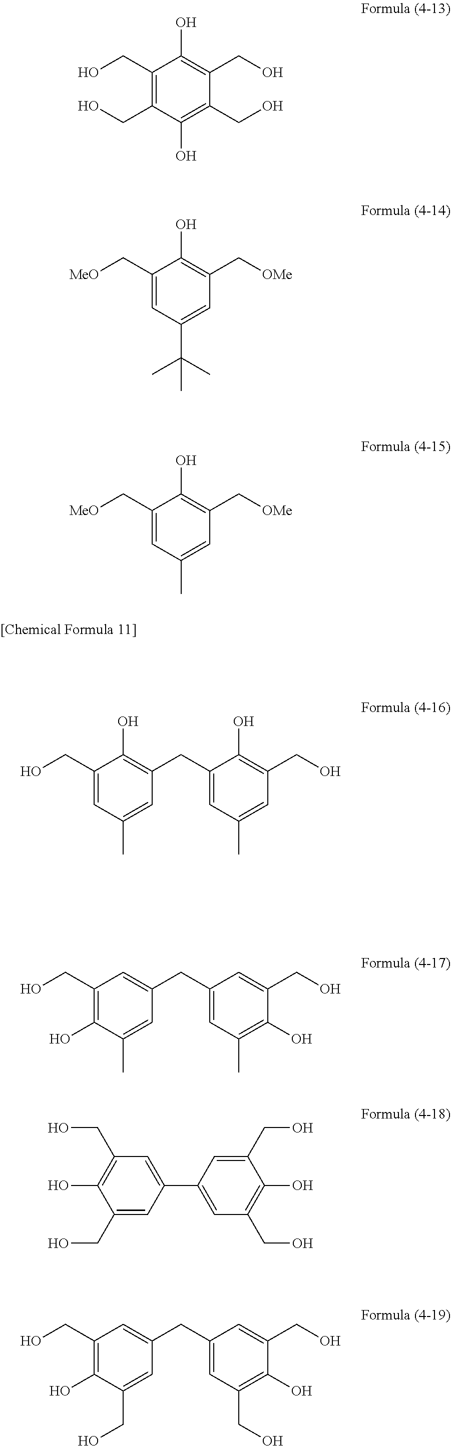

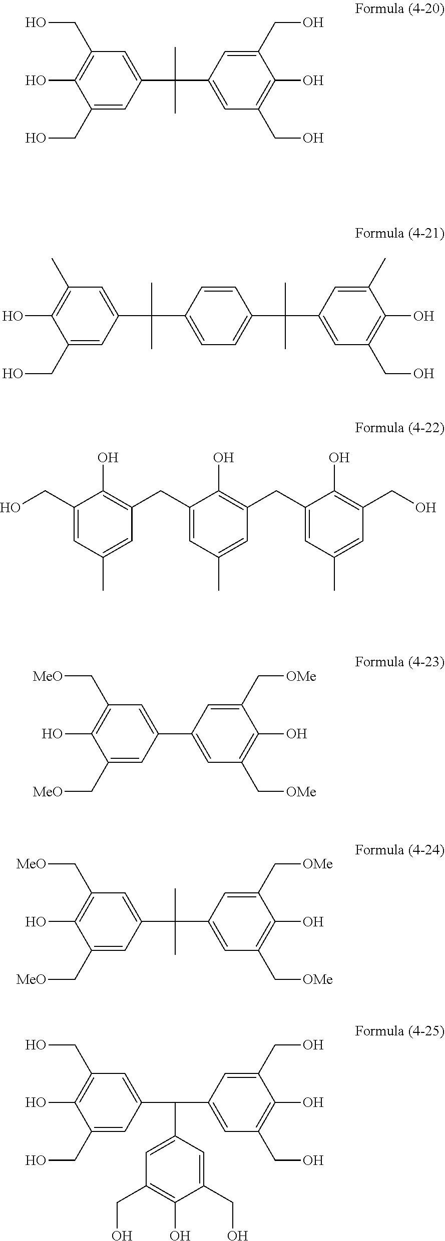 [SMILES: CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O]

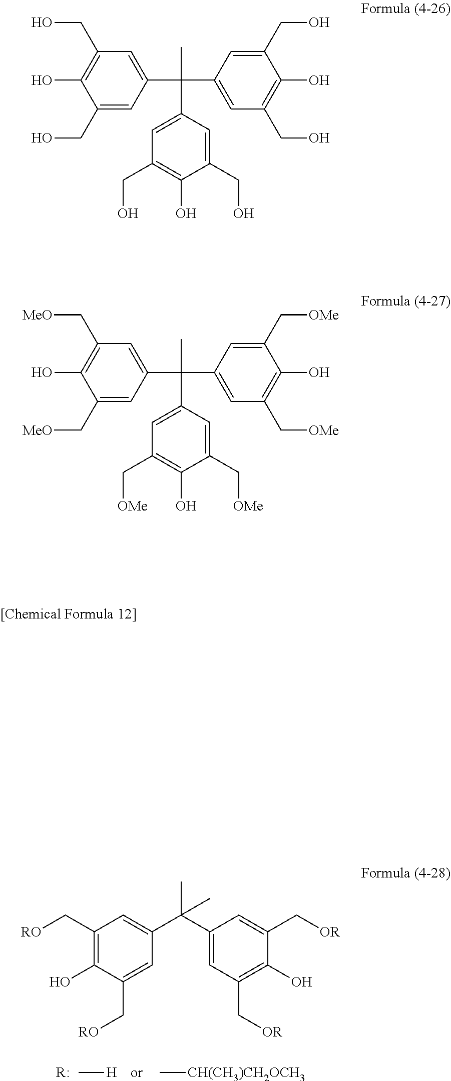

The above compounds are available as products of Asahi Yukizai Corporation and Honshu Chemical Industry Co., Ltd. For example, of the above crosslinking agents, the compound of formula (4-23) is available from Honshu Chemical Industry Co., Ltd. under the trade name TMOM-BP, and the compound of formula (4-24) is available from Asahi Yukizai Corporation under the trade name TM-BIP-A.

The amount of the crosslinking agent used varies depending on the coating solvent used, substrate used, required solution viscosity, required film shape, and other factors, and is 0.001% by mass or more, 0.01% by mass or more, 0.05% by mass or more, 0.5% by mass or more, or 1.0% by mass or more, and 80% by mass or less, 50% by mass or less, 40% by mass or less, 20% by mass or less, or 10% by mass or less of the total solid content. These crosslinking agent may cause crosslinking reaction by self-condensation, but can cause crosslinking reactions with the crosslinking substituents, if any, present in the above polymer of the present invention.

One of these various crosslinking agents may be added each alone or in combination of two or more thereof.

### Acid and/or Salt Thereof and/or Acid Generator

The resist underlayer film-forming composition of the present invention may include an acid and/or a salt thereof and/or an acid generator.

Examples of the acid include p-toluenesulfonic acid, trifluoromethanesulfonic acid, salicylic acid, 5-sulfosalicylic acid, 4-phenolsulfonic acid, camphorsulfonic acid, 4-chlorobenzene sulfonic acid, benzenedisulfonic acid, 1-naphthalene sulfonic acid, carboxylic acid compounds such as citric acid, benzoic acid, hydroxybenzoic acid, naphthalene carboxylic acid, and inorganic acids such as hydrochloric acid, sulfuric acid, nitric acid, and phosphoric acid.

The salt may be a salt of the above-mentioned acid. Although the salt is not limited, but preferable examples thereof include ammonia derivative salts such as trimethylamine and triethylamine salts, pyridine derivative salts, and morpholine derivative salts.

The acid or the salt thereof may be used each alone or in combination of two or more thereof. The amount of the compound is usually within the range of from 0.0001 to 20% by mass, preferably from 0.0005 to 10% by mass, and even more preferably from 0.01 to 5% by mass of the total solid content.

Examples of the acid generator include thermal acid generators and photoacid generators.

Examples of the thermal acid generator include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG-2689, TAG-2700 (manufactured by King Industries, Inc.), SI-45, SI-60, SI-80, SI-100, SI-110, and SI-150 (manufactured by Sanshin Chemical Industry Co., Ltd.), quaternary ammonium salts of trifluoroacetic acid, and alkyl esters of organic sulfonic acids.

The photoacid generator generates an acid when the resist is exposed. This allows adjustment of the acidity of the underlayer film. This is one method for matching the acidity of the underlayer film with the upper layer resist. In addition, the pattern shape of the resist formed on the upper layer can be adjusted by adjusting the acidity of the underlayer film.

Examples of the photoacid generator included in the resist underlayer film-forming composition of the present invention include onium salt compounds, sulfonimide compounds, and disulfonyldiazomethane compounds.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphor sulfonate, bis(4-tert-butylphenyl)iodonium camphor sulfonate, and bis(4-tert-butylphenyl)iodonium, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generator may be used each alone or in combination of two or more thereof.

When an acid generator is used, its ratio is within the range of from 0.01 to 10 parts by mass, from 0.1 to 8 parts by mass, or from 0.5 to 5 parts by mass with respect to 100 parts by mass of the solid content of the resist underlayer film-forming composition.

### Surfactant

The resist underlayer film-forming composition of the present invention may contain a surfactant to further improve the application property to uneven surfaces without pinholes, striations, and the like. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether; polyoxyethylene alkyl allyl ethers such as polyoxyethylene octyl phenol ether and polyoxyethylene nonyl phenol ethers; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorosurfactants such as F-Top [registered trademark] EF301, EF303, and EF₃₅₂ (manufactured by Mitsubishi Materials Electronic Chemicals Co., Ltd.), Megaface [registered trademark] F171, F173, R-30, R-30-N, R-40, and R-40-LM (manufactured by DIC Corporation), Fluorad [registered trademark] FC430 and FC431 (manufactured by Sumitomo 3M Limited.), and Asahi Guard [registered trademark] AG710, Surflon [registered trademark] S-382, SC101, SC102, SC103, SC104, SC105, and SC106 (manufactured by Asahi Glass Co., Ltd.); and organosiloxane polymer KP341 (manufactured by Shin-Etsu Chemical Co., Ltd.). The surfactants may be added each alone or in combination of two or more thereof. The content ratio of the surfactant is, for example, within the range of from 0.01 to 5% by mass of the solid content of the resist underlayer film-forming composition of the present invention, excluding the solvent mentioned below.

The resist underlayer film-forming composition of the present invention may further include additives such as light absorbing agents, rheology modifiers, and adhesion aids. Rheology modifiers are effective in improving the flowability of the underlayer film-forming composition. Adhesion aids are effective in improving adhesion between the semiconductor substrate or resist and the underlayer film.

### Light Absorbing Agent

Preferable examples of the light absorbing agent include commercially available absorbents listed in “Technology and Market of Industrial Dyes” (CMC

Publishing Co., Ltd.) and “Dye Handbook” (edited by The Society of Synthetic Organic Chemistry, Japan), such as C.I. Disperse Yellow 1, 3, 4, 5, 7, 8, 13, 23, 31, 49, 50, 51, 54, 60, 64, 66, 68, 79, 82, 88, 90, 93, 102, 114, and 124; C.I. Disperse Orange 1, 5, 13, 25, 29, 30, 31, 44, 57, 72, and 73; C.I. Disperse Red 1, 5, 7, 13, 17, 19, 43, 50, 54, 58, 30 65, 72, 73, 88, 117, 137, 143, 199, and 210; C.I. Disperse Violet 43; C.I. Disperse Blue 96; C.I. Fluorescent Brightening Agent 112, 135, and 163; C.I. Solvent Orange 2 and 45; C.I. Solvent Red 1, 3, 8, 23, 24, 25, 27, and 49; C.I. Pigment Green 10; and C.I. Pigment Brown 2. The blending amount of the light absorbing agent is usually 10% by mass or less, preferably 5% by mass or less of the total solid content of the resist underlayer film-forming composition.

### Rheology Modifier

The rheology modifier is added mainly to improve the flowability of the resist underlayer film-forming composition, especially in the baking step, to improve the uniformity of the resist underlayer film thickness and the filling property of the resist underlayer film-forming composition into the hole. Specific examples thereof include phthalic acid derivatives such as dimethyl phthalate, diethyl phthalate, diisobutyl phthalate, dihexyl phthalate, and butyl isodecyl phthalate; adipic acid derivatives such as dinormal butyl adipate, diisobutyl adipate, diisooctyl adipate, and octyldecyl adipate; maleic acid derivatives such as di-n-butyl maleate, diethyl maleate, and dinonyl maleate; oleic acid derivatives such as methyl oleate, butyl oleate, and tetrahydrofurfuryl oleate; and stearic acid derivatives such as n-butyl stearate and glyceryl stearate. The blending amount of the rheology modifier is usually less than 30% by mass of the total solid content of the resist underlayer film-forming composition.

### Adhesion Aid

The adhesion aid is added mainly to improve the adhesion between the substrate or resist and the resist underlayer film-forming composition, especially to prevent the resist from peeling off during development. Specific examples thereof include chlorosilanes such as trimethylchlorosilane, dimethylmethylol chlorosilane, methyldiphenylchlorosilane, and chloromethyl dimethylchlorosilane; alkoxysilanes such as trimethylmethoxysilane, dimethyldiethoxysilane, methyldimethoxysilane, dimethylmethylol ethoxysilane, diphenyldimethoxysilane, and phenyltriethoxysilane; silazanes such as hexamethyldisilazane, N,N′-bis(trimethylsilyl)urea, dimethyltrimethylsilylamine, and trimethylsilylimidazole; silanes such as methylol trichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercapto-benzimidazole, 2-mercapto-benzothiazole, 2-mercapto-benzoxazole, urazole, thiouracil, mercaptoimidazole, and mercaptopyrimidine; urea such as 1,1-dimethylurea and 1,3-dimethylurea; and thiourea compounds. The blending amount of the adhesion aid is usually less than 5% by mass, preferably less than 2% by mass of the total solid content of the resist underlayer film-forming composition.

The solid content of the resist underlayer film-forming composition of the present invention is usually within the range of from 0.1 to 70% by mass, preferably from 0.1 to 60% by mass. The solid content is the content ratio of all components in the resist underlayer film-forming composition minus the solvent. The ratio of the above polymer in the solid content is, in the order of increasing preference, from 1 to 100% by mass, from 1 to 99.9% by mass, from 50 to 99.9% by mass, from 50 to 95% by mass, and from 50 to 90% by mass.

One of the measures for evaluating whether the resist underlayer film-forming composition is in a uniform solution state is to observe its passage through a specific microfilter, and the resist underlayer film-forming composition of the present invention passes through a microfilter with a pore diameter of 0.1 μm and exhibits a uniform solution state.

Examples of the microfilter material include fluorine-based resins such as PTFE (polytetrafluoroethylene), PFA (tetrafluoroethylene perfluoroalkyl vinyl ether copolymer), PE (polyethylene), UPE (ultra high molecular weight polyethylene), PP (polypropylene), PSF (polysulfone), PES (polyethersulfone), and nylon. Of these, PTFE (polytetrafluoroethylene) is preferable.

### Resist Underlayer Film

The resist underlayer film may be formed as follows using the resist underlayer film-forming composition of the present invention.

The resist underlayer film is formed by coating the resist underlayer film-forming composition of the present invention on a substrate used for producing semiconductor devices (for example, silicon wafer, silicon dioxide (SiO₂), silicon nitride (SiN), silicon oxide nitride (SiON), titanium nitride (TiN), tungsten (W), glass, ITO, and polyimide substrates, and substrates coated with low-k materials) by an appropriate coating method such as a spinner or a coater followed by baking using a heating means such as a hot plate. The baking conditions are appropriately selected from a baking temperature of from 80° C. to 600° C. and a baking time of from 0.3 to 60 minutes. The baking temperature is preferably from 150° C. to 350° C. and the baking time is preferably from 0.5 to 2 minutes. The atmosphere gas during baking may be air or an inert gas such as nitrogen or argon. The thickness of the underlayer film formed is, for example, within the range of from 10 to 1000 nm, from 20 to 500 nm, from 30 to 400 nm, or from 50 to 300 nm. The substrate may be a quartz substrate, in which case a replica of a quartz imprint mold (mold replica) can be fabricated.

In addition, an inorganic resist underlayer film (hard mask) may also be formed on the organic resist underlayer film of the present invention. It may be formed, for example, by spin-coating the composition for forming a silicon-containing resist underlayer film (inorganic resist underlayer film) formation composition described in WO2009/104552 A1, or by forming a Si-based inorganic material film by a CVD method. The hard mask in the present invention includes both a silicon hard mask and a CVD film.

In addition, an adhesion layer and/or a silicone layer containing 99% by mass or less or 50% by mass or less Si may be formed on the resist underlayer film of the present invention by coating or vapor deposition. It may be formed, for example, by spin-coating the adhesion layer described in JP 2013-202982 A and Japanese Patent No. 5827180, or the composition for forming a silicon-containing resist underlayer film (inorganic resist underlayer film) described in WO2009/104552 A1, or by forming a Si-based inorganic material film by a CVD method.

In addition, by applying the resist underlayer film-forming composition of the present invention onto a semiconductor substrate having a stepped portion and a non-stepped portion (the so-called stepped substrate) followed by baking, a resist underlayer film may be formed with a smaller step between the stepped portion and non-stepped portion.

### Method for Producing Semiconductor Device

The method for producing a semiconductor device according to the present invention comprises the steps of:
forming a resist underlayer film on a semiconductor substrate using the resist underlayer film-forming composition of the present invention;
forming a resist film on the formed resist underlayer film;
forming a resist pattern by irradiating the formed resist film with a light or electron beam followed by development;
etching and patterning the resist underlayer film through the formed resist pattern; and
processing the semiconductor substrate through the patterned resist underlayer film.

The method for producing a semiconductor device according to the present invention comprises the steps of:
forming a resist underlayer film on a semiconductor substrate using the resist underlayer film-forming composition of the present invention;
forming a hard mask on the formed resist underlayer film;
forming a resist film on the formed hard mask;
forming a resist pattern by irradiating the formed resist film with a light or electron beam followed by development;
etching the resist underlayer film through the formed resist pattern; and
removing the hard mask.

The method preferably further comprises the steps of:
forming a vapor-deposited film (spacer) on the underlayer film from which the hard mask has been removed;
processing the formed vapor-deposited film (spacer) by etching;
removing the underlayer film; and
processing the semiconductor substrate with the spacer.

The semiconductor substrate may be a stepped substrate.

The steps of forming a resist underlayer film using the resist underlayer film-forming composition of the present invention are as described above.

A resist film, for example, a layer of photoresist, is then formed on the resist underlayer film. The formation of the photoresist layer may be performed by a well-known method, that is, by applying a photoresist composition solution to the underlayer film and baking it. The film thickness of the photoresist is, for example, within the range of from 50 to 10,000 nm, from 100 to 2000 nm, or from 200 to 1000 nm.

The photoresist formed on the resist underlayer film is not particularly limited as long as it is sensitive to a light used for exposure. Both negative and positive photoresists may be used. Examples thereof include positive photoresists including a novolac resin and 1,2-naphthoquinone diazide sulfonate; chemically amplified photoresists including a binder having a group that is decomposed by acid to increase the alkali dissolution rate and a photoacid generator; chemically amplified photoresists including a low molecular weight compound that is decomposed by acid to increase the alkali dissolution rate of photoresist, an alkaline soluble binder, and a photoacid generator; and chemically amplified photoresists including a binder having a group that is decomposed by acid to increase the alkali dissolution rate, a low molecular weight compound that is decomposed by acid to increase the alkali dissolution rate of the photoresist, and a photoacid generator. Examples thereof include APEX-E (trade name) manufactured by Shipley, PAR 710 (trade name) manufactured by Sumitomo Chemical Co., Ltd., and SEPR 430 (trade name) manufactured by Shin-Etsu Chemical Co., Ltd. Other examples include fluorinated polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Next, a resist pattern is formed by photo or electron beam irradiation and development. First, exposure is performed through a predetermined mask. Near ultraviolet, far ultraviolet, or extreme ultraviolet (for example, EUV (13.5 nm wavelength)) light is used for exposure. Specifically, a KrF excimer laser (wavelength: 248 nm), an ArF excimer laser (wavelength: 193 nm), an F₂ excimer laser (wavelength: 157 nm), and the like may be used. Of these, ArF excimer laser (wavelength: 193 nm) and EUV (wavelength: 13.5 nm) are preferable. After the exposure, post exposure bake may be performed as necessary. The post exposure bake is performed under conditions appropriately selected from a heating temperature of from 70° C. to 150° C. and a heating time of from 0.3 to 10 minutes.

In the present invention, a resist for electron beam lithography may be used instead of a photoresist. The electron beam resist may be either negative or positive type. Examples thereof include chemically amplified resists including an acid generator and a binder having a group that is decomposed by acid to change the alkali dissolution rate; chemically amplified resists including an alkaline soluble binder, an acid generator, and a low molecular weight compound that is decomposed by acid to change the alkali dissolution rate of the resist; chemically amplified resists including an acid generator, a binder having a group that is decomposed by acid to change the alkali dissolution rate of the resist, and a low molecular weight compound that is decomposed by acid to change the alkali dissolution rate of the resist; non-chemically amplified resists including a binder having a group that is decomposed by an electron beam to change the alkali dissolution rate; and non-chemically amplified resists including a binder having a site that is cleaved by an electron beam to change the alkali dissolution rate. Also in the case these electron beam resists are used, resist patterns can be formed in the same manner as in using a photoresist with an electron beam as the irradiation source.

Alternatively, for the purpose of maintaining and improving high resolution and the depth of field, a method in which a substrate with a resist film formed thereon is immersed in a liquid medium for exposure may be adopted. At this time, the resist underlayer film is also required to be resistant to the liquid medium used, and a resist underlayer film that meets this requirement can be formed using the resist underlayer film-forming composition of the present invention.

Next, development is performed with a developing solution. As a result, when a positive photoresist is used, for example, the photoresist in the exposed area is removed, and a pattern of the photoresist is formed.

Examples of the developing solution include alkaline aqueous solutions such as aqueous solutions of alkali metal hydroxides such as potassium oxide and sodium hydroxide, aqueous solutions of quaternary ammonium hydroxides such as tetramethylammonium hydroxide, tetraethylammonium hydroxide, and choline, aqueous solutions of amines such as ethanolamine, propylamine, and ethylenediamine. In addition, surfactants and other agents may be added to these developing solutions. The conditions for development are selected from a temperature of 5 to 50° C. and a time of 10 to 600 seconds.

Then, the inorganic underlayer film (intermediate layer) is removed using the pattern of the photoresist (upper layer) formed in this manner as a protective film, and then the organic underlayer film (underlayer) is removed using the film including the patterned photoresist and the inorganic underlayer film (intermediate layer) as a protective film. Finally, the semiconductor substrate is processed using the patterned inorganic underlayer film (intermediate layer) and organic underlayer film (underlayer) as protective films.

First, the inorganic underlayer film (intermediate layer) in the area where the photoresist has been removed is removed by dry etching to expose the semiconductor substrate. Dry etching of the inorganic underlayer film may be performed using a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane. Dry etching of the inorganic underlayer film is preferably performed using a halogen-based gas, more preferably a fluorine-based gas. Examples of the fluorine-based gas include tetrafluoromethane (CF₄), perfluorocyclobutane (C₄F₈), perfluoropropane (C₃F₈), trifluoromethane, and difluoromethane (CH₂F₂).

Thereafter, the organic underlayer film is removed using the film including the patterned photoresist and the inorganic underlayer film as a protective film. The removal of the organic underlayer film (underlayer) is preferably performed by dry etching using an oxygen-based gas. This is because the inorganic underlayer film containing a large amount of silicon atoms is difficult to remove by dry etching using an oxygen-based gas.

In some cases, wet etching treatment is used to simplify the process and reduce damage to the processed substrate. The resist underlayer film-forming composition of the present invention allows to form a resist underlayer film that exhibits sufficient resistance to the chemical solutions used in wet etching.

Finally, the semiconductor substrate is processed. Processing of the semiconductor substrate is preferably performed by dry etching using a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

In addition, an organic antireflection film may be formed on the upper layer of the resist underlayer film before the photoresist is formed. The antireflection film composition used in this process is not particularly limited, and may be selected from those conventionally used in the lithography process. The antireflection film may be formed by the conventional methods, such as application with a spinner or coater and baking.

In the present invention, after an organic underlayer film is formed on a substrate, an inorganic underlayer film is formed thereon, and a photoresist may be further coated thereon. This narrows the pattern width of the photoresist and prevents pattern collapse, allowing the substrate to be processed by selecting an appropriate etching gas, even when the photoresist is thinly coated. For example, it is possible to process the resist underlayer film using a fluorine-based gas having a sufficiently fast etching rate for a photoresist as an etching gas, and it is possible to process the substrate using a fluorine-based gas having a sufficiently fast etching rate for an inorganic underlayer film, and it is also possible to process the substrate using an oxygen-based gas having a sufficiently fast etching rate for an organic underlayer film.

The resist underlayer film formed from the resist underlayer film-forming composition may also absorb light depending on the wavelength of the light used in the lithography process. In such a case, it can function as an antireflection film with the effect of preventing reflected light from the substrate. Furthermore, the underlayer film formed with the resist underlayer film-forming composition of the present invention can also function as a hard mask. The underlayer film of the present invention is also useful as, for example, a layer to prevent interaction between the substrate and photoresist, a layer that has the function of preventing materials used in the photoresist or substances generated during exposure of the photoresist from having an adverse effect on the substrate, a layer that has the function of preventing diffusion of substances generated from the substrate to the upper layer photoresist during heating and baking, or a barrier layer to reduce the poisoning effect of the photoresist layer by the dielectric layer of the semiconductor substrate.

The underlayer film formed from the resist underlayer film-forming composition may be applied to a substrate with via holes used in the dual damascene process and used as an embedding material that can fill the holes without gaps. It may also be used as a planarization material to flatten the surface of an uneven semiconductor substrate.

### EXAMPLES

The present invention is described in more detail below with reference to examples and others, but the present invention is not limited in any way by the following examples.

The apparatus and others used to measure the weight average molecular weight of the compounds obtained in the synthesis examples are described below.
Apparatus: HLC-8320 GPC manufactured by Tosoh Corporation
GPC column: TSKgel Super-Multipore HZ-N (two columns)
Column temperature: 40° C.
Flow rate: 0.35 mL/min
Eluent: THF
Standard sample: polystyrene

### Synthesis Example 1

10.00 g of diphenylamine (manufactured by Tokyo Chemical Industry Co., Ltd., hereinafter referred to as DPA), 9.23 g of 1-naphthaldehyde (manufactured by Tokyo Chemical Industry Co., Ltd.), 1.14 g of methanesulfonic acid (manufactured by Tokyo Chemical Industry Co., Ltd., hereinafter referred to as MSA), and 47.52 g of propylene glycol monomethyl ether acetate (hereinafter referred to as PGMEA) were placed in a flask. The mixture was then heated to 120° C. under nitrogen, and allowed to react for about 2 hours. After the termination of the reaction, the mixture was precipitated with methanol and dried to obtain a resin (1-1). The weight average molecular weight Mw measured in terms of polystyrene by GPC was about 2,500. The resin obtained was dissolved in cyclohexanone (hereinafter referred to as CYH), and subjected to ion exchange treatment with cation and anion exchange resins for 4 hours to obtain the desired compound solution.

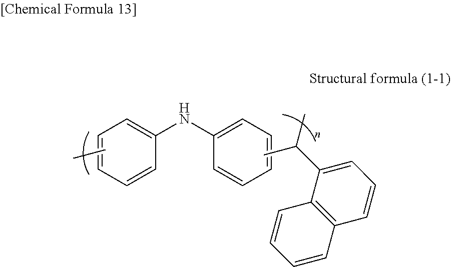

### Synthesis Example 2

10.00 g of DPA, 10.77 g of 4-phenylbenzaldehyde (manufactured by Tokyo Chemical Industry Co., Ltd.), 0.28 g of MSA, and 63.16 g of PGMEA were placed in a flask. The mixture was then heated to 115° C. under nitrogen, and allowed to react for about 4 hours. After the termination of the reaction, the mixture was precipitated with methanol and dried to obtain a resin (1-2). The weight average molecular weight Mw measured in terms of polystyrene by GPC was about 5,700. The resin obtained was dissolved in PGMEA, and subjected to ion exchange treatment with cation and anion exchange resins for 4 hours to obtain the desired compound solution.

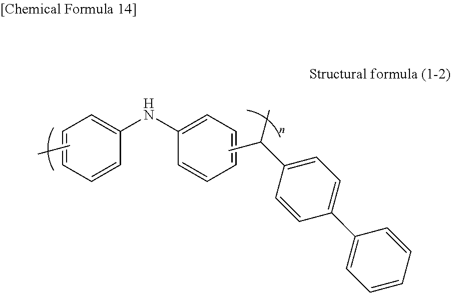

### Synthesis Example 3

10.00 g of DPA, 7.10 g of 4-methylbenzaldehyde (manufactured by Tokyo Chemical Industry Co., Ltd.), 0.28 g of MSA, and 52.15 g of PGMEA were placed in a flask. The mixture was then heated to 115° C. under nitrogen, and allowed to react for about 5 hours. After the termination of the reaction, the mixture was precipitated with methanol and dried to obtain a resin (1-3). The weight average molecular weight Mw measured in terms of polystyrene by GPC was about 4,500. The resin obtained was dissolved in PGMEA, and subjected to ion exchange treatment with cation and anion exchange resins for 4 hours to obtain the desired compound solution.

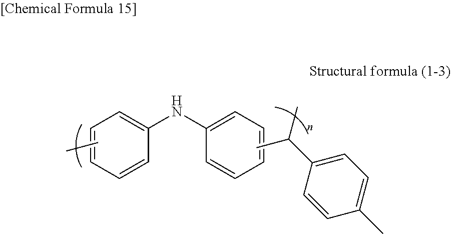

### Synthesis Example 4

10.00 g of DPA, 7.34 g of 4-fluorobenzaldehyde (manufactured by Tokyo Chemical Industry Co., Ltd.), 0.28 g of MSA, and 70.50 g of PGMEA were placed in a flask. The mixture was then heated to reflux under nitrogen and allowed to react for about 4 hours. After the termination of the reaction, the mixture was precipitated with methanol and dried to obtain a resin (1-4). The weight average molecular weight Mw measured in terms of polystyrene by GPC was about 5,700. The resin obtained was dissolved in PGMEA, and subjected to ion exchange treatment with cation and anion exchange resins for 4 hours to obtain the desired compound solution.

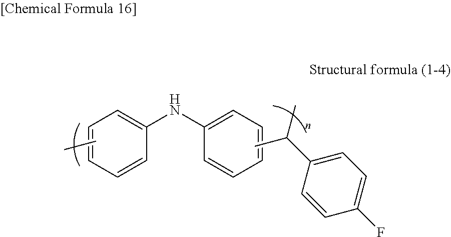

### Synthesis Example 5

10.00 g of DPA, 9.59 g of 4-tert-butylbenzaldehyde (manufactured by Tokyo Chemical Industry Co., Ltd.), 0.57 g of MSA, and 80.62 g of PGMEA were placed in a flask. The mixture was then heated to reflux under nitrogen and allowed to react for about 8 hours. After the termination of the reaction, the mixture was precipitated with methanol and dried to obtain a resin (1-5). The weight average molecular weight Mw measured in terms of polystyrene by GPC was about 4,500. The resin obtained was dissolved in PGMEA, and subjected to ion exchange treatment with cation and anion exchange resins for 4 hours to obtain the desired compound solution.

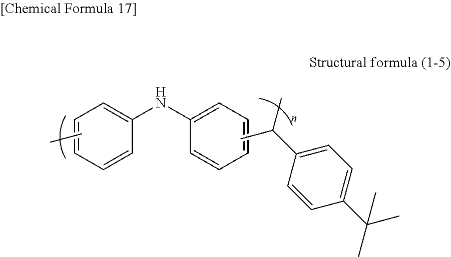

### Synthesis Example 6

10.00 g of DPA, 10.65 g of 9-fluorenone (manufactured by Tokyo Chemical Industry Co., Ltd.), 2.84 g of MSA, and 23.49 g of CYH were placed in a flask. The mixture was then heated to reflux under nitrogen and allowed to react for about 2.5 hours. After the termination of the reaction, the mixture was precipitated with methanol and dried to obtain a resin (1-6). The weight average molecular weight Mw measured in terms of polystyrene by GPC was about 1,300. The resin obtained was dissolved in PGMEA, and subjected to ion exchange treatment with cation and anion exchange resins for 4 hours to obtain the desired compound solution.

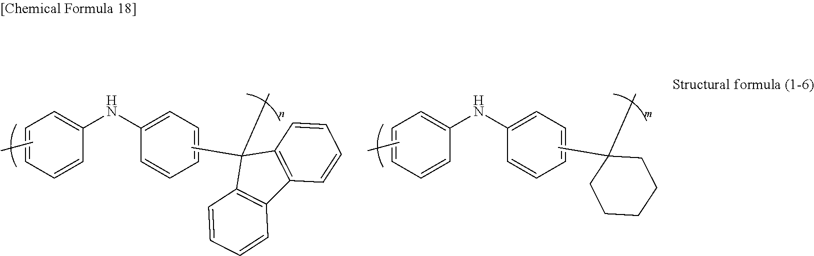

### Synthesis Example 7

10.00 g of DPA, 13.61 g of 1-pyrenecarboxaldehyde, 1.14 g of MSA, 46.19 g of PGMEA, and 11.59 g of N-methyl-2-pyrrolidone were placed in a flask. The mixture was then heated to 120° C. under nitrogen, and allowed to react for about 7.5 hours. After the termination of the reaction, the mixture was precipitated with methanol and dried to obtain a resin (1-7). The weight average molecular weight Mw measured in terms of polystyrene by GPC was about 1,400. The resin obtained was dissolved in CYH, and subjected to ion exchange treatment with cation and anion exchange resins for 4 hours to obtain the desired compound solution.

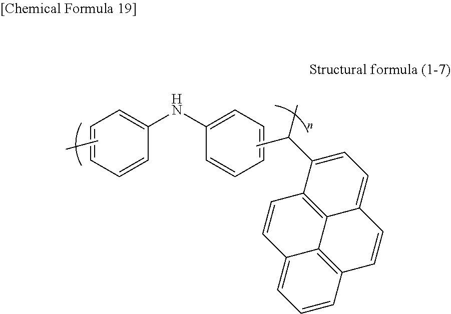

### Synthesis Example 8

10.00 g of N-phenyl-1-naphthylamine (manufactured by Tokyo Chemical Industry Co., Ltd., hereinafter referred to as PNA), 4.84 g of benzaldehyde (manufactured by Tokyo Chemical Industry Co., Ltd.), 0.88 g of MSA, and 36.67 g of PGMEA were placed in a flask. The mixture was then heated to reflux under nitrogen and allowed to react for about 15 minutes. After the termination of the reaction, the mixture was precipitated with methanol and dried to obtain a resin (1-8). The weight average molecular weight Mw measured in terms of polystyrene by GPC was about 5,900. The resin obtained was dissolved in CYH, and subjected to ion exchange treatment with cation and anion exchange resins for 4 hours to obtain the desired compound solution.

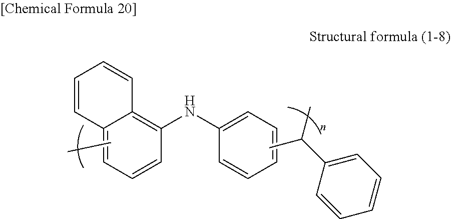

### Synthesis Example 9

10.00 g of PNA, 7.12 g of 1-naphthaldehyde (manufactured by Tokyo Chemical Industry Co., Ltd.), 0.91 g of p-toluenesulfonic acid monohydrate (manufactured by Kanto Chemical Co., Ltd.), and 21.03 g of 1,4-dioxane were placed in a flask. The mixture was then heated to 110° C. under nitrogen, and allowed to react for about 12 hours. After the termination of the reaction, the mixture was precipitated with methanol and dried to obtain a resin (1-9). The weight average molecular weight Mw measured in terms of polystyrene by GPC was about 1,400. The resin obtained was dissolved in PGMEA, and subjected to ion exchange treatment with cation and anion exchange resins for 4 hours to obtain the desired compound solution.

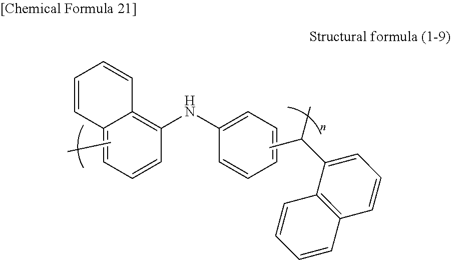

### Synthesis Example 10

8.00 g of PNA, 8.47 g of 1-pyrenecarboxaldehyde, 1.04 g of p-toluenesulfonic acid (manufactured by Tokyo Chemical Industry Co., Ltd.), 16.26 g of toluene, and 16.26 g of 1,4-dioxane were placed in a flask. The mixture was then heated to reflux under nitrogen and allowed to react for about 19.5 hours. After the termination of the reaction, the mixture was precipitated with methanol and dried to obtain a resin (1-10). The weight average molecular weight Mw measured in terms of polystyrene by GPC was about 1,200. The resin obtained was dissolved in cyclohexanone (hereinafter referred to as CYH), and subjected to ion exchange treatment with cation and anion exchange resins for 4 hours to obtain the desired compound solution.

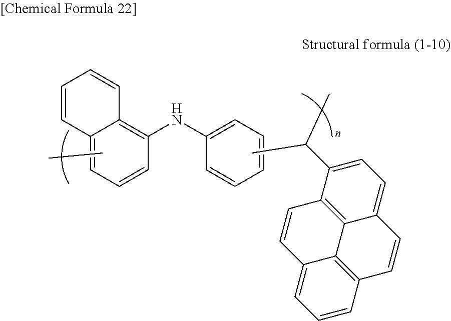

### Synthesis Example 11

15.00 g of PNA, 12.47 g of 4-phenylbenzaldehyde (manufactured by Tokyo Chemical Industry Co., Ltd.), 0.33 g of MSA, and 41.70 g of PGMEA were placed in a flask. The mixture was then heated to 115° C. under nitrogen, and allowed to react for about 2 hours. After the termination of the reaction, the mixture was precipitated with methanol and dried to obtain a resin (1-11). The weight average molecular weight Mw measured by GPC measured in terms of polystyrene by GPC was about 2,600. The resin obtained was dissolved in PGMEA, and subjected to ion exchange treatment with cation and anion exchange resins for 4 hours to obtain the desired compound solution.

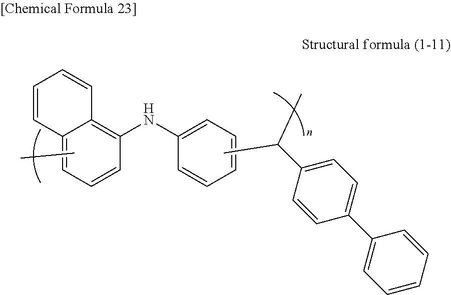

### Synthesis Example 12

35.00 g of carbazole (manufactured by Tokyo Chemical Industry Co., Ltd., hereinafter referred to as Cz), 32.72 g of 1-naphthaldehyde (manufactured by Tokyo Chemical Industry Co., Ltd.), 2.01 g of MSA, and 162.71 g of PGMEA were placed in a flask. The mixture was then heated to 120° C. under nitrogen, and allowed to react for about 7 hours. After the termination of the reaction, the mixture was precipitated with methanol and dried to obtain a compound (1-12). The weight average molecular weight Mw measured by GPC measured in terms of polystyrene by GPC was about 2,600. The resin obtained was dissolved in PGMEA, and subjected to ion exchange treatment with cation and anion exchange resins for 4 hours to obtain the desired compound solution.

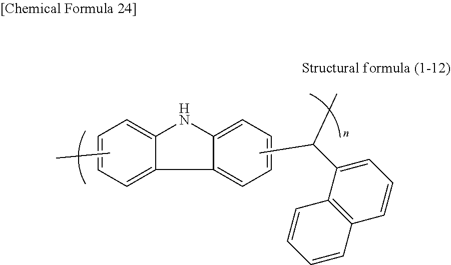

### Synthesis Example 13

15.00 g of Cz, 16.36 g of 4-phenylbenzaldehyde (manufactured by Tokyo

Chemical Industry Co., Ltd.), 0.43 g of MSA, and 47.69 g of PGMEA were placed in a flask. The mixture was then heated to 115° C. under nitrogen, and allowed to react for about 4.5 hours. After the termination of the reaction, the mixture was precipitated with methanol and dried to obtain a compound (1-13). The weight average molecular weight Mw measured in terms of polystyrene by GPC was about 3,600. The resin obtained was dissolved in PGMEA, and subjected to ion exchange treatment with cation and anion exchange resins for 4 hours to obtain the desired compound solution.

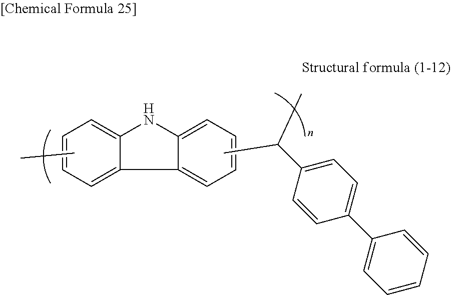

### Synthesis Example 14

7.00 g of Cz, 9.72 g of 1-pyrenecarboxaldehyde, 1.59 g of p-toluenesulfonic acid monohydrate (manufactured by Tokyo Chemical Industry Co., Ltd.), and 27.48 g of PGMEA were placed in a flask. The mixture was then heated to reflux under nitrogen and allowed to react for about 1 hour. After the termination of the reaction, the mixture was precipitated with methanol and dried to obtain a compound (1-14). The weight average molecular weight Mw measured in terms of polystyrene by GPC was about 1,300. The resin obtained was dissolved in CYH, and subjected to ion exchange treatment with cation and anion exchange resins for 4 hours to obtain the desired compound solution.

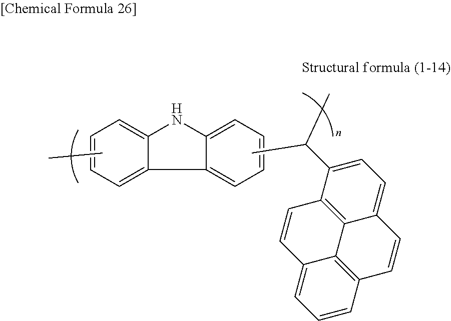

### Synthesis Example 15

8.00 g of Cz, 8.63 g of 9-fluorenone (manufactured by Tokyo Chemical Industry Co., Ltd.), 2.30 g of MSA, and 18.93 g of PGMEA were placed in a flask. The mixture was then heated to reflux under nitrogen, precipitated with methanol after about 1.5 hours, and dried to obtain a resin (1-15). The weight average molecular weight Mw measured by GPC measured in terms of polystyrene by GPC was about 2,600. The resin obtained was dissolved in PGMEA, and subjected to ion exchange treatment with cation and anion exchange resins for 4 hours to obtain the desired polymer solution.

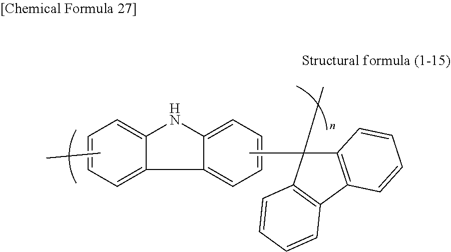

### Synthesis Example 16

15 8.00 g of Cz, 0.77 g of 1-naphthol (manufactured by Tokyo Chemical Industry Co., Ltd.), 9.59 g of 9-fluorenone (manufactured by Tokyo Chemical Industry Co., Ltd.), 1.28 g of MSA, and 36.46 g of PGMEA were placed in a flask. The mixture was then heated to reflux under nitrogen, precipitated with methanol after about 13 hours, and dried to obtain a resin (1-16). The weight average molecular weight Mw measured in terms of polystyrene by GPC was about 2,800. The resin obtained was dissolved in PGMEA, and subjected to ion exchange treatment with cation and anion exchange resins for 4 hours to obtain the desired polymer solution.

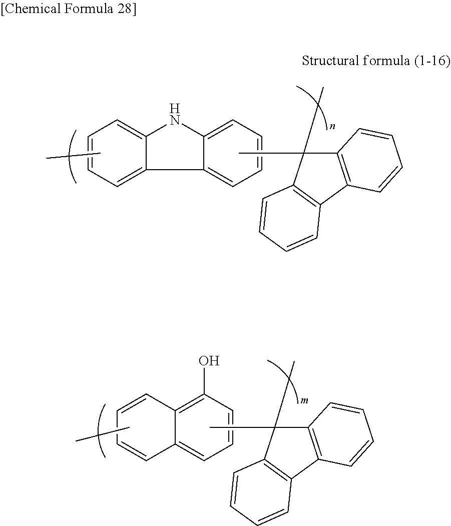

### Synthesis Example 17

6.00 g of Cz, 4.48 g of p-naphtholbenzein (manufactured by Fujifilm Wako Pure Chemical Corporation), 8.63 g of 9-fluorenone (manufactured by Tokyo Chemical Industry Co., Ltd.), 1.15 g of MSA, and 30.39 g of PGMEA were placed in a flask. The mixture was then heated to reflux under nitrogen, precipitated with methanol after about 14.5 hours, and dried to obtain a resin (1-17). The weight average molecular weight Mw measured in terms of polystyrene by GPC was about 3,000. The resin obtained was dissolved in PGMEA, and subjected to ion exchange treatment with cation and anion exchange resins for 4 hours to obtain the desired polymer solution.

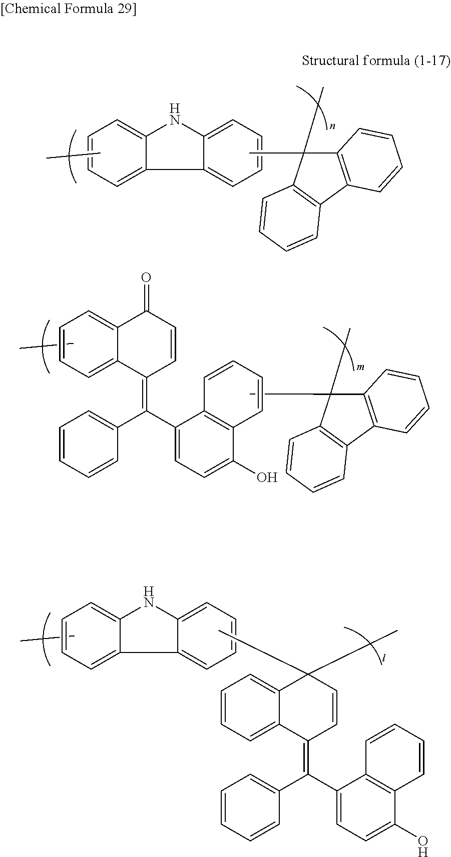

### Comparative Synthesis Example 1

8.00 g of N-ethylcarbazole (manufactured by Tokyo Chemical Industry Co., Ltd.), 4.35 g of benzaldehyde (manufactured by Tokyo Chemical Industry Co., Ltd.), 0.59 g of MSA, and 30.19 g of PGMEA were placed in a flask. The mixture was then heated to reflux under nitrogen and allowed to react for about 3 hours. After the termination of the reaction, the mixture was precipitated with methanol and dried to obtain a compound (2-1). The weight average molecular weight Mw measured in terms of polystyrene by GPC was 950. The resin obtained was dissolved in CYH, and subjected to ion exchange treatment with cation and anion exchange resins for 4 hours to obtain the desired compound solution.

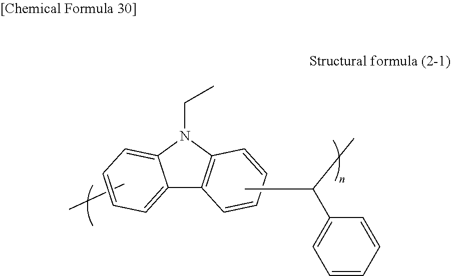

### Comparative Synthesis Example 2

10.00 g of triphenylamine (manufactured by Tokyo Chemical Industry Co., Ltd.), 7.43 g of 4-phenylbenzaldehyde (manufactured by Tokyo Chemical Industry Co., 25 Ltd.), 0.39 g of MSA, and 53.46 g of PGMEA were placed in a flask. The mixture was then heated to 100° C. under nitrogen, and allowed to react for about 15 hours. After the termination of the reaction, the mixture was precipitated with methanol and dried to obtain a compound (2-2). The weight average molecular weight Mw measured in terms of polystyrene by GPC was 1,900. The resin obtained was dissolved in CYH, and subjected to ion exchange treatment with cation and anion exchange resins for 4 hours to obtain the desired compound solution.

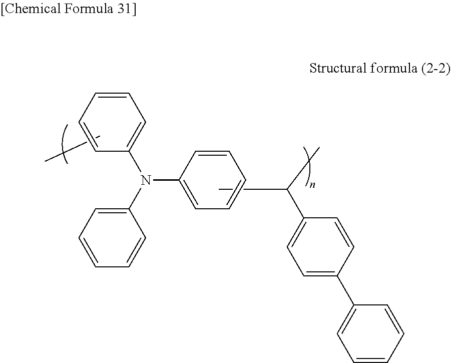

### Comparative Synthesis Example 3

10.00 g of TEP-TPA (manufactured by Asahi Yukizai Corporation), 4.48 g of benzaldehyde (manufactured by Tokyo Chemical Industry Co., Ltd.), 0.81 g of MSA, and 35.67 g of PGME were placed in a flask. The mixture was then heated to reflux under nitrogen and allowed to react for about 4 hours. After the termination of the reaction, the mixture was precipitated with a methanol/water mixed solution and dried to obtain a compound (2-1). The weight average molecular weight Mw measured in terms of polystyrene by GPC was about 195,000. The resin obtained was dissolved in PGME, and subjected to ion exchange treatment with cation and anion exchange resins for 4 hours to obtain the desired compound solution.

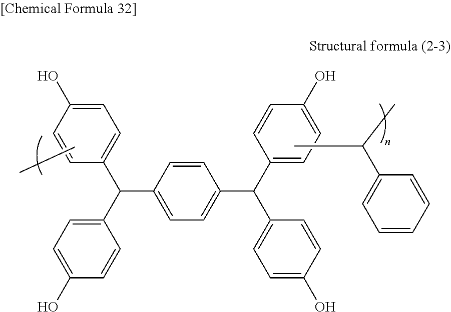

### Comparative Synthesis Example 4

10.00 g of 1,5-dihydroxynaphthalene (manufactured by Tokyo Chemical Industry Co., Ltd.), 6.62 g of benzaldehyde (manufactured by Tokyo Chemical Industry Co., Ltd.), 1.20 g of MSA, and 41.58 g of PGMEA were placed in a flask. The mixture was then heated to reflux under nitrogen and allowed to react for about 1.5 hours. After the termination of the reaction, the mixture was precipitated with methanol and dried to obtain a compound (2-2). The weight average molecular weight Mw measured in terms of polystyrene by GPC was about 5,300. The resin obtained was dissolved in PGME, and subjected to ion exchange treatment with cation and anion exchange resins for 4 hours to obtain the desired compound solution.

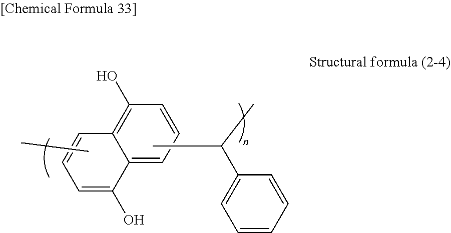

### Comparative Synthesis Example 5

20.00 g of 9,9-bis(4-hydroxyphenyl)fluorene, 6.06 g of benzaldehyde (manufactured by Tokyo Chemical Industry Co., Ltd.), 1.10 g of MSA, and 40.73 g of PGMEA were placed in a flask. The mixture was then heated to reflux under nitrogen and allowed to react for about 6.5 hours. After the termination of the reaction, the mixture was precipitated with a methanol/water mixed solution and dried to obtain a compound (2-3). The weight average molecular weight Mw measured in terms of polystyrene by GPC was about 3,850. The resin obtained was dissolved in PGMEA, and subjected to ion exchange treatment with cation and anion exchange resins for 4 hours to obtain the desired compound solution.

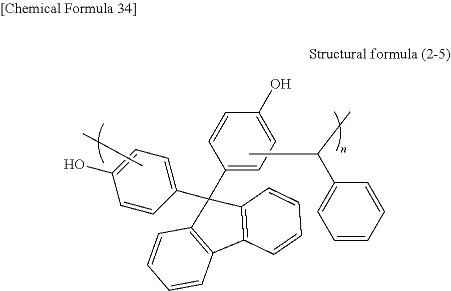

### Example 1

A resin solution (solid content: 18.14% by mass) was obtained in Synthesis Example 1. To 3.21 g of this resin solution, 0.15 g of PL-LI (manufactured by Midori Kagaku Co., Ltd.), 1.09 g of PGME containing 2% by mass of TAG2689 (manufactured by King Industries Inc.), 0.06 g of PGMEA containing 1% by mass of a surfactant (manufactured by DIC Corporation, Megafac R-40), 2.79 g of PGMEA, 1.78 g of PGME, and 5.92 g of CYH were added and dissolved. The resulting solution was filtered through a polytetrafluoroethylene microfilter having a pore diameter of 0.1 μm to prepare a solution of a resist underlayer film-forming composition.

### Example 2

A resin solution (solid content: 20.53% by mass) was obtained in Synthesis Example 2. To 30.43 g of this resin solution, 0.15 g of PL-LI, 11.71 g of PGME containing 2% by mass of pyridinium p-toluenesulfonic acid (manufactured by Midori Kagaku Co., Ltd.), 0.62 g of PGMEA containing 1% by mass of a surfactant, 63.98 g of PGMEA, 55.11 g of PGME, and 66.59 g of CYH were added and dissolved. The resulting solution was filtered through a polytetrafluoroethylene microfilter having a pore diameter of 0.1 μm to prepare a solution of a resist underlayer film-forming composition.

### Example 3

A resin solution (solid content: 20.08% by mass) was obtained in Synthesis Example 3. To 31.11 g of this resin solution, 1.56 g of PL-LI, 11.71 g of PGME containing 2% by mass of pyridinium p-toluenesulfonic acid, 0.62 g of PGMEA containing 1% by mass of a surfactant, 129.88 g of PGMEA, and 55.11 g of PGME were added and dissolved. The resulting solution was filtered through a polytetrafluoroethylene microfilter having a pore diameter of 0.1 μm to prepare a solution of a resist underlayer film-forming composition.

### Example 4

A resin solution (solid content: 20.35% by mass) was obtained in Synthesis Example 4. To 30.70 g of this resin solution, 1.56 g of PL-LI, 11.71 g of PGME containing 2% by mass of pyridinium p-toluenesulfonic acid, 0.62 g of PGMEA containing 1% by mass of a surfactant, 130.29 g of PGMEA, and 55.11 g of PGME were added and dissolved. The resulting solution was filtered through a polytetrafluoroethylene microfilter having a pore diameter of 0.1 μm to prepare a solution of a resist underlayer film-forming composition.

### Example 5

A resin solution (solid content: 20.88% by mass) was obtained in Synthesis Example 5. To 29.92 g of this resin solution, 1.56 g of PL-LI, 11.71 g of PGME containing 2% by mass of pyridinium p-toluenesulfonic acid, 0.62 g of PGMEA containing 1% by mass of a surfactant, 130.07 g of PGMEA, and 55.11 g of PGME were added and dissolved. The resulting solution was filtered through a polytetrafluoroethylene microfilter having a pore diameter of 0.1 μm to prepare a solution of a resist underlayer film-forming composition.

### Example 6

A resin solution (solid content: 19.94% by mass) was obtained in Synthesis Example 6. To 31.33 g of this resin solution, 1.56 g of PL-LI, 11.71 g of PGME containing 2% by mass of pyridinium p-toluenesulfonic acid, 0.62 g of PGMEA containing 1% by mass of a surfactant, 129.66 g of PGMEA, and 55.11 g of PGME were added and dissolved. The resulting solution was filtered through a polytetrafluoroethylene microfilter having a pore diameter of 0.1 μm to prepare a solution of a resist underlayer film-forming composition.

### Example 7

A resin solution (solid content: 19.78% by mass) was obtained in Synthesis Example 7. To 2.35 g of this resin solution, 0.12 g of PL-LI, 0.87 g of PGME containing 2% by mass of TAG2689, 0.05 g of PGMEA containing 1% by mass of a surfactant, 2.83 g of PGMEA, 2.02 g of PGME, and 6.75 g of CYH were added and dissolved. The resulting solution was filtered through a polytetrafluoroethylene microfilter having a pore diameter of 0.1 μm to prepare a solution of a resist underlayer film-forming composition.

### Example 8

A resin solution (solid content: 17.72% by mass) was obtained in Synthesis Example 8. To 2.63 g of this resin solution, 0.12 g of PL-LI, 0.87 g of PGME containing 2% by mass of TAG2689, 0.05 g of PGMEA containing 1% by mass of a surfactant, 2.83 g of PGMEA, 2.02 g of PGME, and 6.48 g of CYH were added and dissolved. The resulting solution was filtered through a polytetrafluoroethylene microfilter having a pore diameter of 0.1 μm to prepare a solution of a resist underlayer film-forming composition.

### Example 9

A resin solution (solid content: 30.00% by mass) was obtained in Synthesis Example 9. To 1.55 g of this resin solution, 0.12 g of PL-LI, 0.87 g of PGME containing 2% by mass of TAG2689, 0.05 g of PGMEA containing 1% by mass of a surfactant, 8.95 g of PGMEA, and 3.46 g of PGME were added and dissolved. The resulting solution was filtered through a polytetrafluoroethylene microfilter having a pore diameter of 0.1 μm to prepare a solution of a resist underlayer film-forming composition.

### Example 10

A resin solution (solid content: 30.00% by mass) was obtained in Synthesis Example 10. To 1.55 g of this resin solution, 0.12 g of PL-LI, 0.87 g of PGME containing 2% by mass of TAG2689, 0.05 g of PGMEA containing 1% by mass of a surfactant, 2.83 g of PGMEA, 2.02 g of PGME, and 7.55 g of CYH were added and dissolved. The resulting solution was filtered through a polytetrafluoroethylene microfilter having a pore diameter of 0.1 μm to prepare a solution of a resist underlayer film-forming composition.

### Example 11

A resin solution (solid content: 21.70% by mass) was obtained in Synthesis Example 11. To 19.90 g of this resin solution, 0.86 g of PL-LI, 3.24 g of PGME containing 2% by mass of pyridinium p-toluenesulfonic acid, 0.43 g of PGMEA containing 1% by mass of a surfactant, 41.89 g of PGMEA, 40.25 g of PGME, and 43.43 g of CYH were added and dissolved. The resulting solution was filtered through a polytetrafluoroethylene microfilter having a pore diameter of 0.1 μm to prepare a solution of a resist underlayer film-forming composition.

### Example 12

A resin solution (solid content: 30.30% by mass) was obtained in Synthesis Example 12. To 1.54 g of this resin solution, 0.12 g of PL-LI, 0.87 g of PGME containing 2% by mass of TAG2689, 0.05 g of PGMEA containing 1% by mass of a surfactant, 8.96 g of PGMEA, and 3.46 g of PGME were added and dissolved. The resulting solution was filtered through a polytetrafluoroethylene microfilter having a pore diameter of 0.1 μm to prepare a solution of a resist underlayer film-forming composition.

### Example 13

A resin solution (solid content: 21.56% by mass) was obtained in Synthesis Example 13. To 2.55 g of this resin solution, 0.14 g of PL-LI, 0.55 g of PGME containing 2% by mass of TAG2689, 0.06 g of PGMEA containing 1% by mass of a surfactant, 11.45 g of PGMEA, and 5.25 g of PGME were added and dissolved. The resulting solution was filtered through a polytetrafluoroethylene microfilter having a pore diameter of 0.1 μm to prepare a solution of a resist underlayer film-forming composition.

### Example 14

A resin solution (solid content: 20.71% by mass) was obtained in Synthesis Example 14. To 2.25 g of this resin solution, 0.12 g of PL-LI, 0.87 g of PGME containing 2% by mass of TAG2689, 0.05 g of PGMEA containing 1% by mass of a surfactant, 2.83 g of PGMEA, 2.02 g of PGME, and 6.86 g of CYH were added and dissolved. The resulting solution was filtered through a polytetrafluoroethylene microfilter having a pore diameter of 0.1 μm to prepare a solution of a resist underlayer film-forming composition.

### Example 15

A resin solution (solid content: 30.00% by mass) was obtained in Synthesis Example 15. To 1.55 g of this resin solution, 0.12 g of PL-LI, 0.87 g of PGME containing 2% by mass of TAG2689, 0.05 g of PGMEA containing 1% by mass of a surfactant, 8.95 g of PGMEA, and 3.46 g of PGME were added and dissolved. The resulting solution was filtered through a polytetrafluoroethylene microfilter having a pore diameter of 0.1 μm to prepare a solution of a resist underlayer film-forming composition.

### Example 16

A resin solution (solid content: 16.73% by mass) was obtained in Synthesis Example 16. To 4.08 g of this resin solution, 0.10 g of PL-LI, 0.68 g of PGME containing 2% by mass of pyridinium p-toluenesulfonic acid, 0.07 g of PGMEA containing 1% by mass of a surfactant, 9.97 g of PGMEA, and 5.09 g of PGME were added and dissolved. The resulting solution was filtered through a polytetrafluoroethylene microfilter having a pore diameter of 0.1 μm to prepare a solution of a resist underlayer film-forming composition.

### Example 17

A resin solution (solid content: 16.96% by mass) was obtained in Synthesis Example 17. To 4.03 g of this resin solution, 0.10 g of PL-LI, 0.68 g of PGME containing 2% by mass of pyridinium p-toluenesulfonic acid, 0.07 g of PGMEA containing 1% by mass of a surfactant, 10.0 g of PGMEA, and 5.09 g of PGME were added and dissolved. The resulting solution was filtered through a polytetrafluoroethylene microfilter having a pore diameter of 0.1 μm to prepare a solution of a resist underlayer film-forming composition.

### Comparative Example 1

A resin solution (solid content: 18.47% by mass) was obtained in Comparative Synthesis Example 1. To 2.52 g of this resin solution, 0.12 g of PL-LI, 0.87 g of PGME containing 2% by mass of TAG2689, 0.05 g of PGMEA containing 1% by mass of a surfactant, 2.83 g of PGMEA, 2.02 g of PGME, and 6.58 g of CYH were added and dissolved. The resulting solution was filtered through a polytetrafluoroethylene microfilter having a pore diameter of 0.1 μm to prepare a solution of a resist underlayer film-forming composition.

### Comparative Example 2

A resin solution (solid content: 18.08% by mass) was obtained in Comparative Synthesis Example 2. To 2.58 g of this resin solution, 0.12 g of TMOM-BP (manufactured by Honshu Chemical Industry Co., Ltd.), 0.87 g of PGME containing 2% by mass of pyridinium p-toluenesulfonic acid, 0.05 g of PGMEA containing 1% by mass of a surfactant, 1.89 g of PGMEA, 3.02 g of PGME, and 11.5 g of CYH were added and dissolved. The resulting solution was filtered through a polytetrafluoroethylene microfilter having a pore diameter of 0.1 μm to prepare a solution of a resist underlayer film-forming composition.

### Comparative Example 3

A resin solution (solid content: 15.22% by mass) was obtained in Comparative Synthesis Example 3. To 3.06 g of this resin solution, 0.12 g of PL-LI, 0.87 g of PGME containing 2% by mass of pyridinium p-toluenesulfonic acid, 0.05 g of PGMEA containing 1% by mass of a surfactant, 5.77 g of PGMEA, and 10.13 g of PGME were added and dissolved. The resulting solution was filtered through a polytetrafluoroethylene microfilter having a pore diameter of 0.1 μm to prepare a solution of a resist underlayer film-forming composition.

### Comparative Example 4

A resin solution (solid content: 18.21% by mass) was obtained in Comparative Synthesis Example 4. To 2.56 g of this resin solution, 0.12 g of PL-LI, 0.87 g of PGME containing 2% by mass of pyridinium p-toluenesulfonic acid, 0.05 g of PGMEA containing 1% by mass of a surfactant, 1.89 g of PGMEA, and 14.51 g of PGME were added and dissolved. The resulting solution was filtered through a polytetrafluoroethylene microfilter having a pore diameter of 0.1 μm to prepare a solution of a resist underlayer film-forming composition.

### Comparative Example 5

A resin solution (solid content: 20.18% by mass) was obtained in Comparative Synthesis Example 5. To 2.31 g of this resin solution, 0.12 g of PL-LI, 0.87 g of PGME containing 2% by mass of pyridinium p-toluenesulfonic acid, 0.05 g of PGMEA containing 1% by mass of a surfactant, 11.69 g of PGMEA, and 4.96 g of PGME were added and dissolved. The resulting solution was filtered through a polytetrafluoroethylene microfilter having a pore diameter of 0.1 μm to prepare a solution of a resist underlayer film-forming composition.

### Comparative Example 6

A resin solution (solid content: 15.22% by mass) was obtained in Comparative Synthesis Example 3. To 3.06 g of this resin solution, 0.12 g of PL-LI, 0.87 g of PGME containing 2% by mass of TAG2689, 0.05 g of PGMEA containing 1% by mass of a surfactant, 5.77 g of PGMEA, and 10.13 g of PGME were added and dissolved. The resulting solution was filtered through a polytetrafluoroethylene microfilter having a pore diameter of 0.1 μm to prepare a solution of a resist underlayer film-forming composition.

### Comparative Example 7

A resin solution (solid content: 18.21% by mass) was obtained in Comparative Synthesis Example 4. To 2.56 g of this resin solution, 0.12 g of PL-LI, 0.87 g of PGME containing 2% by mass of TAG2689, 0.05 g of PGMEA containing 1% by mass of a surfactant, 1.89 g of PGMEA, and 14.51 g of PGME were added and dissolved. The resulting solution was filtered through a polytetrafluoroethylene microfilter having a pore diameter of 0.1 μm to prepare a solution of a resist underlayer film-forming composition.

### Comparative Example 8

A resin solution (solid content: 20.18% by mass) was obtained in Comparative Synthesis Example 5. To 2.31 g of this resin solution, 0.12 g of PL-LI, 0.87 g of PGME containing 2% by mass of TAG2689, 0.05 g of PGMEA containing 1% by mass of a surfactant, 11.69 g of PGMEA, and 4.96 g of PGME were added and dissolved. The resulting solution was filtered through a polytetrafluoroethylene microfilter having a pore diameter of 0.1 μm to prepare a solution of a resist underlayer film-forming composition.

### Elution Test in Resist Solvent

Each of the solutions of the resist underlayer film-forming compositions prepared in Comparative Example 1-8 and Example 1-17 was applied to a silicon wafer, respectively, using a spin coater, and baked on a hot plate at 240° C. for 60 seconds or 350° C. for 60 seconds to form a resist underlayer film (film thickness: 65 nm). These resist underlayer films were immersed in a mixed solvent of PGME/PGMEA in a ratio of 7/3, which is a general-purpose thinner. The resist underlayer film was insoluble. And it was confirmed that the film had a sufficient curability.

### Measurement of Sublimate Amount

The sublimate amount was measured using the sublimate measuring apparatus described in WO 2007/111147 A. Sublimates are components that are released from the film into the atmosphere during baking. Each of the resist underlayer film-forming compositions prepared in Comparative Example 1-2 and Example 1-17 was applied to a silicon wafers, respectively, and the amount of sublimates when the film thickness reached 65 nm after baking at 240° C. for 60 seconds was measured. The samples with a less amount of sublimates compared to Comparative Example were judged as “○”.

TABLE 1

| Sample | Baking temperature | Amount of sublimates |
|---|---|---|
| Comparative Example 1 | 240° C. | x |
| Comparative Example 2 | 240° C. | x |
| Example 1 | 240° C. | ∘ |
| Example 2 | 240° C. | ∘ |
| Example 3 | 240° C. | ∘ |
| Example 4 | 240° C. | ∘ |
| Example 5 | 240° C. | ∘ |
| Example 6 | 240° C. | ∘ |
| Example 7 | 240° C. | ∘ |
| Example 8 | 240° C. | ∘ |
| Example 9 | 240° C. | ∘ |
| Example 10 | 240° C. | ∘ |
| Example 11 | 240° C. | ∘ |
| Example 12 | 240° C. | ∘ |
| Example 13 | 240° C. | ∘ |
| Example 14 | 240° C. | ∘ |
| Example 15 | 240° C. | ∘ |
| Example 16 | 240° C. | ∘ |
| Example 17 | 240° C. | ∘ |

Comparative Examples gave a large amount of sublimates and thus they would have a risk of contaminating the apparatus. In contrast, Examples gave a small amount of sublimates and thus they would permit suppressing contamination of the apparatus.

### Application Property Test

Each of the solutions of the resist underlayer film-forming compositions prepared in Comparative Example 1-2 and Example 1-17 was applied to a silicon wafer, respectively, using a spin coater, and baked on a hot plate at 240° C. for 60 seconds to form a resist underlayer film. The film thickness of the resist underlayer film was then measured, and a value was calculated according to “[Variation in film thickness (maximum film thickness−minimum film thickness)]/[Average film thickness]×100”. When this value is low, the application property can be judged to be good. When the application property of an example is better than the corresponding comparative example, the example was judged as “○”.

TABLE 2

| Sample | Baking temperature | Application property |
|---|---|---|
| Comparative Example 1 | 240° C. | x |
| Comparative Example 2 | 240° C. | x |
| Example 1 | 240° C. | ∘ |
| Example 2 | 240° C. | ∘ |
| Example 3 | 240° C. | ∘ |
| Example 4 | 240° C. | ∘ |
| Example 5 | 240° C. | ∘ |
| Example 6 | 240° C. | ∘ |
| Example 7 | 240° C. | ∘ |
| Example 8 | 240° C. | ∘ |
| Example 9 | 240° C. | ∘ |
| Example 10 | 240° C. | ∘ |
| Example 11 | 240° C. | ∘ |
| Example 12 | 240° C. | ∘ |
| Example 13 | 240° C. | ∘ |
| Example 14 | 240° C. | ∘ |
| Example 15 | 240° C. | ∘ |
| Example 16 | 240° C. | ∘ |
| Example 17 | 240° C. | ∘ |

### Chemical Solution Resistance Test

Each of the solutions of the resist underlayer film-forming compositions prepared in Comparative Example 1-6 and Example 1-17 was applied to SiON, respectively, using a spin coater. The coating was baked on a hot plate at 240° C. for 60 seconds or 350° C. for 60 seconds to form a resist underlayer film (film thickness: 65 nm thick). Thereon were formed a silicon hard mask layer (film thickness: 20 nm) and a resist layer (AR²⁷⁷²JN-14, manufactured by JSR Corporation, film thickness: 120 nm). The product was exposed at a wavelength of 193 nm using a mask followed by development to obtain a resist pattern. Then, the resist pattern was dry etched using fluorine-based gas and oxygen-based gas using an etching apparatus manufactured by Lam Research Co., Ltd., and the resulting resist pattern was transferred to the resist underlayer film. By the confirmation with CG-4100 manufactured by Hitachi Technology Co., Ltd., the pattern shape was confirmed to have provided a 50 nm line pattern.

The pattern wafer obtained here was cut and immersed in SARC-410 (manufactured by Nihon Entegris G.K.) heated to 30° C. After immersion, the wafer was taken out, rinsed with water, and dried. The dried wafer was observed with a scanning electron microscope (Regulus 8240) to check whether the pattern shape formed by the resist underlayer film was not deteriorated or whether the pattern was not collapsed. When the pattern shape is not deteriorated and is not suffered from collapse, its resistance to the chemical solution is high.

As compared with Comparative Example, a case wherein neither pattern shape deterioration nor pattern collapse occurs even after immersion in the chemical solution for a longer time was judged as “○”. The cases in which the polymer caused neither pattern shape deterioration nor pattern collapse even after immersion in the chemical solution for a longer period of time than the polymer in Comparative Examples were judged as “○”.

TABLE 3

| | | Pattern shape | Collapse of | Chem- |
|---|---|---|---|---|
| | | after | pattern after | ical |
| | Baking | chemical | chemical | solution |
| | temper- | solution | solution | resis- |
| Sample | ature | treatment | treatment | tance |
| Comparative Example 1 | 240° C. | Curved | Collapsed | x |
| Comparative Example 2 | 240° C. | Curved | Collapsed | x |
| Comparative Example 3 | 240° C. | Curved | Collapsed | x |
| Comparative Example 4 | 240° C. | Curved | Collapsed | x |
| Comparative Example 5 | 240° C. | Curved | Collapsed | x |
| Comparative Example 6 | 240° C. | Curved | Collapsed | x |
| Example 1 | 350° C. | Vertical | No collapse | ∘ |
| Example 2 | 240° C. | Vertical | No collapse | ∘ |
| Example 3 | 240° C. | Vertical | No collapse | ∘ |
| Example 4 | 240° C. | Vertical | No collapse | ∘ |
| Example 5 | 240° C. | Vertical | No collapse | ∘ |
| Example 6 | 240° C. | Vertical | No collapse | ∘ |
| Example 7 | 240° C. | Vertical | No collapse | ∘ |
| Example 8 | 240° C. | Vertical | No collapse | ∘ |
| Example 9 | 240° C. | Vertical | No collapse | ∘ |
| Example 10 | 240° C. | Vertical | No collapse | ∘ |
| Example 11 | 240° C. | Vertical | No collapse | ∘ |
| Example 12 | 240° C. | Vertical | No collapse | ∘ |
| Example 13 | 240° C. | Vertical | No collapse | ∘ |
| Example 14 | 240° C. | Vertical | No collapse | ∘ |
| Example 15 | 350° C. | Vertical | No collapse | ∘ |
| Example 16 | 240° C. | Vertical | No collapse | ∘ |
| Example 17 | 240° C. | Vertical | No collapse | ∘ |

### INDUSTRIAL APPLICABILITY

Thus, the material according to the present patent provides a low sublimation amount, whereby permits suppression of contamination of apparatuses. Such a low amount of sublimates would result in a good application property. In addition, having a small amount of hydroxyl groups, the polymer can suppress pattern shape deterioration and pattern collapse after the treatment with a chemical solution. As the result, having a high chemical solution resistance to alkaline chemical solutions, the material can be applied to any processes in which chemical solutions are used.

1. A resist underlayer film-forming composition comprising a solvent and a polymer comprising a unit structure (A) represented by the following formula (1): 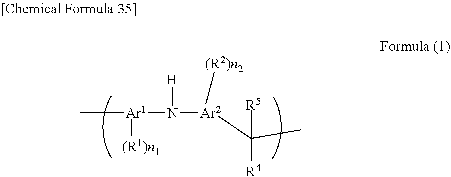
wherein Ar¹ and Ar² each represent a benzene ring or naphthalene ring, Ar¹ and Ar² may be bonded via a single bond;
R¹ and R² are groups substituting hydrogen atoms on the rings of Ar¹ and Ar², respectively, and are selected from the group consisting of a halogen atom, a nitro group, an amino group, a cyano group, an alkyl group having 1 to 10 carbon atoms, an alkenyl group having 2 to 10 carbon atoms, an alkynyl group having 2 to 10 carbon atoms, an aryl group having 6 to 40 carbon atoms, and combinations thereof, and the alkyl, alkenyl, alkynyl, and aryl groups may contain an ether, ketone, or ester bond,
R⁴ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, and an aryl group having 6 to 40 carbon atoms, and the alkyl, alkenyl, alkynyl, and aryl groups may contain an ether, ketone, or ester bond;
R⁵ is selected from the group consisting of a hydrogen atom, a trifluoromethyl group, an aryl group having 6 to 40 carbon atoms, and a heterocyclic group, wherein the aryl and heterocyclic groups may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms, and the alkyl, alkenyl, alkynyl, and aryl groups may contain an ether, ketone, or ester bond;
R⁴ and R⁵ may be combined with a carbon atom to which they are bonded to form a ring; and
n1 and n2 are each an integer of from 0 to 3.

2. The resist underlayer film-forming composition according to claim 1, wherein Ar¹ and Ar² in formula (1) are benzene rings.

3. The resist underlayer film-forming composition according to claim 1, wherein R⁵ in formula (1) is a hydrogen atom, R⁴ is an aryl group having 6 to 40 carbon atoms, and the aryl group may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms.

4. The resist underlayer film-forming composition according claim 1, wherein R⁵ in formula (1) is a hydrogen atom, R⁴ is an aryl group having 6 to 40 carbon atoms, and the aryl group may be substituted with an aryl group having 6 to 40 carbon atoms.

5. The resist underlayer film-forming composition according to claim 1, wherein R⁵ in formula (1) is a hydrogen atom, and R⁴ is a group comprising a combination of optionally substituted benzene rings.

6. The resist underlayer film-forming composition according to claim 1, further comprising a crosslinking agent.

7. The resist underlayer film-forming composition according to claim 1, further comprising an acid and/or an acid generator.

8. The resist underlayer film-forming composition according to claim 1, wherein the solvent has a boiling point of 160° C. or higher.

9. A resist underlayer film, which is a baked product of a coating film comprising the resist underlayer film-forming composition according to claim 1.

10. A method for producing a semiconductor device, comprising the steps of:
forming a resist underlayer film on a semiconductor substrate using the resist underlayer film-forming composition according to claim 1;
forming a resist film on the formed resist underlayer film;
forming a resist pattern by irradiating the formed resist film with a light or electron beam followed by development;
etching and patterning the resist underlayer film through the formed resist pattern; and
processing the semiconductor substrate through the patterned resist underlayer film.

11. A method for producing a semiconductor device, comprising the steps of:
forming a resist underlayer film on a semiconductor substrate using the resist underlayer film-forming composition according to claim 1;
forming a hard mask on the formed resist underlayer film;
forming a resist film on the formed hard mask;
forming a resist pattern by irradiating the formed resist film with a light or electron beam followed by development;
etching the hard mask through the formed resist pattern;
etching the resist underlayer film through the etched hard mask; and
removing the hard mask.

12. The method for producing a semiconductor device according to claim 11, further comprising the steps of:
forming a vapor-deposited film (spacer) on the underlayer film from which the hard mask has been removed;
processing the formed vapor-deposited film (spacer) by etching;
removing the underlayer film; and
processing the semiconductor substrate with the spacer.

13. The method for producing a semiconductor device according claim 10, wherein the semiconductor substrate is a stepped substrate.

14. A polymer comprising a unit structure (A) represented by the following formula (1): 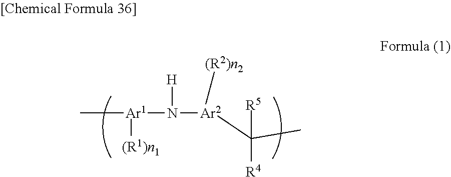
wherein Ar¹ and Ar² each represent a benzene ring or naphthalene ring, Ar¹ and Ar² may be bonded via a single bond;
R¹ and R² are groups substituting hydrogen atoms on the rings of Ar¹ and Ar², respectively, and are selected from the group consisting of a halogen atom, a nitro group, an amino group, a cyano group, an alkyl group having 1 to 10 carbon atoms, an alkenyl group having 2 to 10 carbon atoms, an alkynyl groups having 2 to 10 carbon atoms, an aryl groups having 6 to 40 carbon atoms, and combinations thereof, and the alkyl, alkenyl, alkynyl, and aryl groups may contain an ether, ketone, or ester bond,
R⁴ is a group comprising a combination of optionally substituted benzene rings including a biphenyl group, the benzene ring may be substituted with a halogen atom, a nitro group, an amino group, a cyano group, a trifluoromethyl group, an alkyl group having 1 to 10 carbon atoms, an alkoxy group having 1 to 10 carbon atoms, an alkenyl group having 2 to 10 carbon atoms, an alkynyl group having 2 to 10 carbon atoms, or an aryl group having 6 to 40 carbon atoms, and the alkyl, alkenyl, alkynyl, and aryl groups may contain an ether, ketone, or ester bond,
R⁵ is a hydrogen atom, and
n1 and n2 are each an integer of from 0 to 3.

15. The polymer according to claim 14, wherein Ar¹ and Ar² in formula (1) are benzene rings.

16. The polymer according to claim 14, wherein R⁴ in formula (1) is an optionally substituted biphenyl group.
